(19) United States
(12) Patent Application Publication
(10) Pub. No.: US 2025/0169156 A1
(43) Pub. Date: May 22, 2025

(54) HIGH ELECTRON MOBILITY TRANSISTOR WITH INTEGRATED DIODE

(71) Applicant: TEXAS INSTRUMENTS INCORPORATED, Dallas, TX (US)

(72) Inventors: Zhikai Tang, Sunnyvale, CA (US); Ujwal Radhakrishna, San Jose, CA (US); Jungwoo Joh, Allen, TX (US); Timothy Merkin, Princeton, TX (US)

(21) Appl. No.: 18/757,062

(22) Filed: Jun. 27, 2024

Related U.S. Application Data
(60) Provisional application No. 63/601,315, filed on Nov. 21, 2023.

(51) Int. Cl. H01L 27/06; H01L 21/8252; H01L 29/20; H01L 29/66; H01L 29/778; H01L 29/872

(52) U.S. Cl. CPC H10D 84/01; H10D 8/051; H10D 8/60; H10D 30/015; H10D 30/475; H10D 62/8503; H10D 84/05; H10D 84/811

(57) ABSTRACT

A semiconductor device includes a substrate, a semiconductor layer stack on the substrate, and a gate, a source, and a drain formed on or in the semiconductor layer stack. The semiconductor layer stack may include a non-silicon channel layer and a barrier layer on the channel layer. At least one of the substrate or the semiconductor layer stack includes a diode, a first terminal of the diode electrically coupled to the source, and a second terminal of the diode electrically coupled to the drain.

### CROSS-REFERENCE TO RELATED APPLICATION

This application claims the benefit of and priority to U.S. Provisional Application No. 63/601,315, filed Nov. 21, 2023, entitled “Avalanche-Capable GaN Power Transistor,” which is assigned to the assignee hereof and is herein incorporated by reference in its entirety for all purposes.

### BACKGROUND

A high electron mobility transistor (HEMT) may include a heterojunction formed using different semiconductor materials, where a channel may be formed near the heterojunction. The channel may be turned on or off by applying an appropriate voltage level on a gate structure. Gallium nitride (GaN)-based HEMT devices generally have high breakdown field, high electron mobility, low resistance, high current, faster-switching speed, high thermal conductivity, and excellent reverse-recovery performance, and thus may be suitable for applications where a low-loss and high-efficiency performance is desired, such as power electronics (e.g., power switches), radio frequency (RF) circuits, and the like.

### SUMMARY

This Summary is provided to introduce examples of disclosed concepts in a simplified form, which are further described below in the Detailed Description including the drawings provided.

According to certain aspects, a semiconductor device may include a substrate, a semiconductor layer stack on the substrate, and a gate, a source, and a drain formed on or in the semiconductor layer stack. The semiconductor layer stack may include a non-silicon channel layer and a barrier layer on the channel layer. At least one of the substrate or the semiconductor layer stack includes a diode, a first terminal of the diode electrically coupled to the source, and a second terminal of the diode electrically coupled to the drain.

According to certain aspects, a method may include forming a semiconductor layer stack on a substrate, the semiconductor layer stack including a non-silicon channel layer and a barrier layer in the channel layer, where at least one of the substrate or the semiconductor layer stack includes a diode; forming a gate on a side of the barrier layer opposing the channel layer; forming a source on or in the semiconductor layer stack, the source electrically coupled to a first terminal of the diode; and forming a drain on or in the semiconductor layer stack, the drain electrically coupled to a second terminal of the diode.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1A is a cross-sectional view of an example of a high electron mobility transistor (HEMT).

FIG. 1B is a schematic of an example of a semiconductor device including an HEMT and a diode.

FIG. 2 is a cross-sectional view of an example of a semiconductor device including an HEMT and a diode on a same semiconductor die.

FIGS. 3A and 3B are cross-sectional views of an example of a semiconductor device including an HEMT and a diode on a same semiconductor die.

FIGS. 4A-4E illustrate an example of a process of fabricating the semiconductor device of FIGS. 3A and 3B.

FIGS. 5A and 5B are cross-sectional views of an example of a semiconductor device including an HEMT and a diode on a same semiconductor die.

FIGS. 6A-6E illustrate an example of a process of fabricating the semiconductor device of FIGS. 5A and 5B.

FIGS. 7A and 7B are cross-sectional views of an example of a semiconductor device including an HEMT and a diode on a same semiconductor die.

FIGS. 8A-8F illustrate an example of a process of fabricating the semiconductor device of FIGS. 7A and 7B.

FIGS. 9A and 9B are cross-sectional views of an example of a semiconductor device including an HEMT and a diode on a same semiconductor die.

FIGS. 10A-10F illustrate an example of a process of fabricating the semiconductor device of FIGS. 9A and 9B.

FIGS. 11A and 11B are cross-sectional views of an example of a semiconductor device including an HEMT and a diode on a same semiconductor die.

FIGS. 12A-12D illustrate an example of a process of fabricating the semiconductor device of FIGS. 11A and 11B.

FIGS. 13A and 13B are cross-sectional views of an example of a semiconductor device including an HEMT and a diode on a same semiconductor die.

FIGS. 14A-14D illustrate an example of a process of fabricating the semiconductor device of FIGS. 13A and 13B.

FIG. 15 is a cross-sectional view of an example of a semiconductor device including an HEMT and a Schottky diode on a same semiconductor die.

FIG. 16 includes a graph illustrating simulation results of the breakdown of different GaN-based transistors.

FIG. 17 includes a schematic illustrating an example of an operation of an GaN-based transistor including an integrated diode.

FIGS. 18A and 18B illustrate simulation results of the circuit shown by the schematic of FIG. 17 during a switching operation.

FIG. 19 includes a flowchart illustrating an example of a process of fabricating a semiconductor device including an HEMT and a diode on a same semiconductor die.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to semiconductor devices. In some examples, a semiconductor device includes a high electron mobility transistor (HEMT) and a diode integrated on a same semiconductor die. In some examples, the diode is or otherwise function as an avalanche diode that can provide avalanche capability. Many benefits and advantages may be achieved by the monolithic integration, such as low parasitic resistance and inductance, no additional packaging or additional bonding to PCB, shorter response time, tunable avalanche energy level, lower cost, smaller device, and the like, as described in more detail below.

A GaN-based field-effect transistor, such as a GaN-based HEMT, may include a heterojunction formed by a channel layer (e.g., a GaN layer) and a barrier layer (e.g., an aluminum gallium nitride (AlGaN) layer). High-density two-dimensional electron gas (2DEG) can be formed at the heterojunction to function as a conductive channel. For example, the 2DEG can have a sheet charge density greater than about 1.0×10¹³ cm⁻², and thus can have a low static on-state resistance. GaN-based HEMTs are attractive for high frequency and high power applications due to, for example, the high breakdown field, high electron mobility, low static resistance, and high thermal conductivity of GaN-based HEMTs.

In high-voltage applications and applications where repetitive avalanche breakdown may be needed, such as automotive electric control units, it may be desirable that the power devices have avalanche diodes with recoverable breakdown capability to protect the power devices against damages that may otherwise be caused by the high voltages. A diode may experience avalanche breakdown under a high reverse bias voltage when the high electric field applied by the high reverse bias voltage is high enough to accelerate the minority carriers to ionize atoms in the crystal lattice, where the carriers generated by the ionization may ionize more atoms to cause a chain reaction that may significantly increases the current without significant increasing the voltage across the diode. The avalanche breakdown is reversible when the applied voltage is lower than the breakdown voltage. Thus, an avalanche diode may clamp the voltage across a circuit and/or divert current from the circuit, thereby protecting the circuit against high voltage and current surges that may otherwise cause irreversible and catastrophic breakdown, such as dielectric breakdown. An avalanche diode may have a lower doping density and thus a wider depletion region. Silicon metal-oxide-semiconductor field-effect transistors ((MOSFETs) have diffusion regions (drain/source) and the substrate of opposite polarities, and the p-n junctions between the diffusion regions and the substrate provide body diodes, which can function as avalanche diodes. But lateral HEMTs may not have such diffusion regions and hence may not have diodes with recoverable breakdown capability to protect the HEMTs against high voltages and/or high currents. Therefore, the HEMTs may be permanently (irreversibly) damaged, for example, during unclamped inductively switching (UIS) test.

In some examples disclosed herein, a semiconductor device may include a substrate, a semiconductor layer stack on the substrate, and a gate, a source, and a drain formed on or in the semiconductor layer stack. The semiconductor layer stack may include an HEMT formed by a non-silicon channel layer and a barrier layer on the channel layer. At least one of the substrate or the semiconductor layer stack may include a diode formed therein, where a first terminal of the diode may be electrically coupled to the source, and a second terminal of the diode may be electrically coupled to the drain. The diode may function as an avalanche diode having the recoverable breakdown capability to protect the semiconductor device against high voltages and/or high currents. The substrate may include, for example, silicon, silicon carbide, silicon on insulator (SOI), sapphire, gallium nitride (GaN), engineered GaN, or another semiconductor material having a bandgap wider than the bandgap of silicon. The channel layer may include, for example, GaN, AlGaN, or Indium Aluminum Nitride (InAlN).

In some examples, the diode may be formed in the substrate. For example, the diode may be a vertical diode (e.g., along a thickness direction of the semiconductor substrate) formed by a p-doped semiconductor layer and an n-doped semiconductor layer in the substrate, or may be a lateral diode (e.g., perpendicular to the thickness direction of the semiconductor substrate) formed by a doped semiconductor layer and an oppositely doped semiconductor region in the doped semiconductor layer. In some examples, the diode may be formed in the semiconductor layer stack, such as a vertical diode formed by a p-doped semiconductor layer and an n-doped semiconductor layer in the semiconductor layer stack. The doped semiconductor layer(s) may be formed in the substrate or the semiconductor layer stack by, for example, epitaxial growth and/or ion implantation. The doped semiconductor region may be formed by, for example, ion implantation in a selected region of a doped semiconductor layer. In some examples, the diode may be a Schottky diode formed by a semiconductor layer and a Schottky metal contact.

The semiconductor device including an HEMT and a monolithically integrated diode disclosed herein may have avalanche capability for high voltage/current surge protection and may be used in applications where repetitive avalanche breakdown is needed, such as in some automotive electric control units. Compared with a device where the diode is external to a chip or a semiconductor die including the HEMT, the interconnects between the monolithically integrated HEMT and diode can have much lower parasitic resistance and inductance due to the monolithic integration. Therefore, the device may have shorter response time during switching, and may be more suitable for high-speed switching. The avalanche breakdown voltage or energy level of the avalanche diode can be tuned by, for example, tuning the doping densities or doping profiles of the two terminals of the diode, and/or the dimensions of the two terminals of the diode, such as the thickness of a lightly doped semiconductor layer of the diode. Because no additional packaging or board-level bonding processes are needed, the cost of fabricating the devices may be lower.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2DEG at the heterojunction interface.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

GaN-based HEMTs include heterostructures that may induce two-dimensional electron gas (2DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer near the interface of the heterostructure to form a conductive channel in the GaN layer (which is thus referred to as the channel layer). Compared to silicon-based transistors, GaN-based transistors generally have high breakdown electric field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement mode high electron mobility transistor (e-HEMT) or a depletion mode high electron mobility transistor (d-HEMT). For example, the gate structure of an e-HEMT may include a p-GaN layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2DEG channel under the p-GaN gate structure, such that the conductive path between the source and drain may be disabled and thus the e-HEMT may be turned off when no gate drive voltage is applied to the gate electrical contact. When a positive voltage above the gate threshold voltage is applied to the gate electrical contact, the gate structure may attract electrons such that the 2DEG under the gate structure may be replete with electrons, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2DEG under the gate structure may not be depleted such that the conductive path in the channel layer between the drain structure and the source structure may be enabled even without a positive gate voltage. A d-HEMT can be turned off by applying a negative gate voltage to the gate electrical contact to deplete electrons from the 2DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

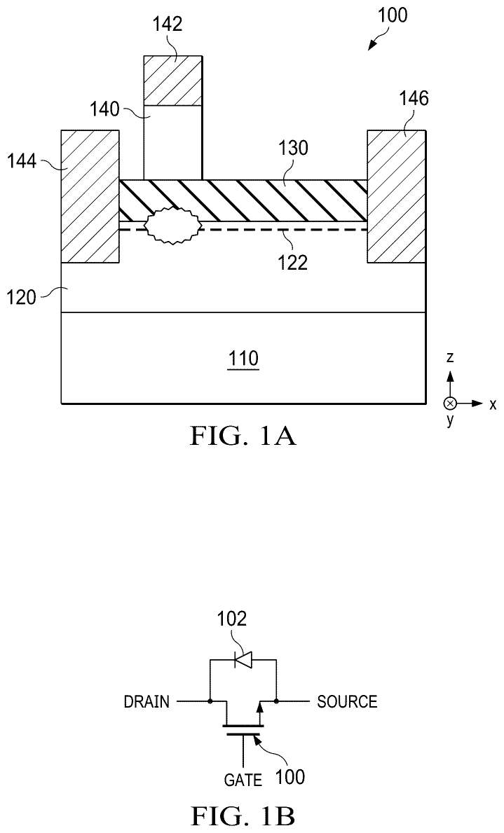

FIG. 1A is a cross-sectional view of an example of a high electron mobility transistor (HEMT) 100. In the illustrated example, HEMT 100 is an enhancement mode GaN-based transistor that includes a substrate 110, a channel layer 120, a barrier layer 130, a gate structure, a source structure, and a drain structure. Substrate 110 may include, for example, a silicon substrate, a silicon carbide substrate, a semiconductor-on-insulator (SOI) substrate, a sapphire substrate, a gallium nitride (GaN) substrate, a gallium arsenide (GaAs) substrate, an engineered GaN substrate (a Qromis™ Substrate Technology (QST) substrate), a substrate including another semiconductor material that has a bandgap wider than the bandgap of silicon, or any other suitable substrate. In one example, substrate 110 may include a bulk silicon substrate, and may also include one or more transition layers or buffer layers of suitable materials for accommodating the lattice mismatch between substrate 110 and channel layer 120 (e.g., to reduce or minimize lattice defect generation and/or propagation in channel layer 120). For example, the transition layers or buffer layers may have a gradient concentration of one or more elements in a surface normal direction (e.g., z direction) of substrate 110 to gradually change the lattice constant.

Channel layer 120 and barrier layer 130 may be epitaxially grown on substrate 110 to form a heterostructure that may induce a 2DEG 122 near the interface between channel layer 120 and barrier layer 130 due to the different energy band structures of channel layer 120 and barrier layer 130. 2DEG 112 may conduct current in a two-dimensional plane (e.g., an x-y plane). In some examples, channel layer 120 may be a portion of substrate 110. Channel layer 120 may include, for example, a GaN layer, an AlGaN layer, or an InAlN layer. In some examples, the material of channel layer 120 may include an unintentionally doped material, such as a material doped by diffusion of dopants from another layer, or includes an intrinsic material. Barrier layer 130 may include, for example, an AlGaN layer. Other materials may also be used for channel layer 120 and barrier layer 130. For example, channel layer 120 may include indium aluminum gallium nitride (InᵢAlⱼGa₁₋ᵢ₋ⱼN) (where 0≤i≤1, 0−j≤1, and 0≤i+j≤1), and barrier layer 130 may include indium aluminum gallium nitride (InₖAlₜGa₁₋ₖ₋ₗN) (where 0≤k≤1, 0≤l≤1, and 0≤k+l≤1).

The gate structure of HEMT 100 may include a gate semiconductor layer 140 over an upper surface of barrier layer 130. In some examples, gate semiconductor layer 140 may include a p-doped semiconductor layer. For example, gate semiconductor layer 140 may include a GaN layer, or more generally, an InₘAlₙGa₁₋ₘ₋ₙN layer (where 0≤m<1, 0≤n<1, and 0≤m+n≤1). The p-type dopants for doping gate semiconductor layer 140 may include magnesium (Mg), carbon (C), zinc (Zn), and the like, or a combination thereof. In examples where gate semiconductor layer 140 includes GaN doped with a p-type dopant, gate semiconductor layer 140 may be referred to as a p-GaN layer. In some examples, a concentration of the dopant that is electrically activated in gate semiconductor layer 140 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 140 may be formed by epitaxial growth and selective etching using an etch mask, or may be formed by selective area growth using a growth mask. The etch mask or growth mask may define the shape and size of gate semiconductor layer 140. The doping density and the thickness of p-doped gate semiconductor layer 140 and the thickness of barrier layer 130 under gate semiconductor layer 140 may be selected such that the p-doped gate semiconductor layer 140 may deplete 2DEG 122 under gate semiconductor layer 140, such that HEMT 100 is turned off without a positive gate voltage and may be turned on by applying a positive voltage to the gate structure.

A gate electrical contact 142 may be formed on gate semiconductor layer 140 to apply a gate voltage to gate semiconductor layer 140. Gate electrical contact 142 may be electrically coupled to a gate drive circuit though electrical interconnects such as conductive traces and/or vias (now shown). In some examples, gate electrical contact 142 may laterally extend beyond gate semiconductor layer 140 to form a gate field plate, for example, to reduce current collapse and dynamic on-state resistance, and increase the breakdown voltage. Gate electrical contact 142 may include one or more metal and/or metal alloy materials having high electrical conductivity.

At the source region of HEMT 100, a source electrical contact 144 may extend through barrier layer 130 and contact a source region of channel layer 120. Source electrical contact 144 may include a metal or metal alloy and may form a low-barrier metal-to-semiconductor contact (e.g., an ohmic contact) with channel layer 120. In some examples, source electrical contact 144 may not extend through barrier layer 130 and may be electrically coupled to the source region of channel layer 120 through, for example, tunneling effects. In some examples, one or more source field plates may be formed and may be coupled to source electrical contact 144. The source field plates may be used to reduce current collapse and dynamic on-state resistance and/or increase the breakdown voltage of HEMT 100.

At the drain region of HEMT 100, a drain electrical contact 146 may extend through barrier layer 130 and contact a drain region of channel layer 120. Drain electrical contact 146 may include a metal or metal alloy and may form a low-barrier metal-to-semiconductor contact (e.g., an ohmic contact) with channel layer 120. In some examples, drain electrical contact 146 may not extend through barrier layer 130 and may be electrically coupled to the source region of channel layer 120 through, for example, tunneling effects.

Each of gate electrical contact 142, source electrical contact 144, and drain electrical contact 146 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or a combination thereof. In some examples, the alloy may include, for example, titanium tungsten aluminum (TiWAl) or titanium aluminum nitride (TiAlN), or a combination thereof.

In some examples, HEMT 100 may include one or more dielectric layers (not shown in FIG. 1A) that isolate and protect the gate structure, drain structure, and source structure. The one or more dielectric layers may include a same dielectric material or different dielectric materials deposited in one or more deposition processes. For example, the one or more dielectric layers may include an oxide-based material or a nitride-based material, such as silicon oxide (e.g., a phosphosilicate glass (PSG)), aluminum oxide, silicon nitride, and the like. In some examples, the one or more dielectric layers may further include one or more etch stop layers, such as silicon nitride (SiN) and the like, for controlling the etch depth of etching processes (e.g., for patterning a dielectric or metal layer).

In some examples, the electrical contacts or other metal electrical interconnects in HEMT 100 may each include one or more metal barrier layers and/or one or more adhesion layers (e.g., titanium nitride (TiN), tantalum nitride (TaN), and the like, or a combination thereof) between the metal material (e.g., Al, Cu, W, and the like, or a combination thereof) and the one or more dielectric layers. The one or more metal barrier layers may prevent the diffusion of metal atoms into the one or more dielectric layers. The one or more adhesion layers may be used to improve the adhesion of the metal material to the dielectric material of the one or more dielectric layers to reduce or avoid defects and reliability issues such as interfacial delamination.

As described above, in high-voltage applications and applications where repetitive avalanche breakdown may be needed, such as automotive electric control units, it may be desirable that the power devices have avalanche diodes with recoverable breakdown capability to protect the power devices against high-voltage damages. An avalanche diode may experience avalanche breakdown under high reverse bias voltage when the high electric field applied by the high reverse bias voltage is high enough to accelerate the minority carriers to ionize atoms in the crystal lattice, where the carriers generated by the ionization may ionize more atoms to create a chain reaction that may significantly increases the current without significant voltage increase across the diode. The avalanche breakdown is reversible when the applied voltage is lower than the breakdown voltage. Thus, the avalanche diode may clamp the voltage across a circuit and/or divert current from the circuit, thereby protecting the circuit against high voltage and current surges that may otherwise cause irreversible and catastrophic breakdown, such as dielectric breakdown. An avalanche diode may generally have a lower doping density and thus a wider depletion region.

Silicon MOSFETs may have inherent p-n junction body diodes that can function as avalanche diodes. As shown in FIG. 1A, unlike MOSFET transistors, HEMT 100 formed by epitaxial growth of channel layer 120 and barrier layer 130 may not have a built-in avalanche diode with recoverable breakdown capability to protect the HEMTs against high voltages and/or high currents. Therefore, the HEMTs may be permanently (irreversibly) damaged during unclamped inductively switching (UIS) test. In some examples, to prevent irreversible and catastrophic breakdown (e.g., dielectric breakdown) and provide the repetitive avalanche breakdown capability, a discrete diode made of a material different from the material of the HEMT, such as a silicon based diode on a silicon die, may be bonded to the HEMT die through board-level or die-level bonding to form a device with an HEMT and an avalanche diode in a same package or on a same board.

FIG. 1B is a schematic of an example of a device including HEMT 100 and a diode 102. The anode of diode 102 may be electrically coupled to source electrical contact 144 of HEMT 100, whereas the cathode of diode 102 may be electrically coupled to drain electrical contact 146 of HEMT 100. When HEMT 100 is turned on, the voltage difference between the drain terminal and the source terminal of HEMT 100 may be low, a low reverse bias voltage may be applied to diode 102, and thus diode 102 may prevent current from flowing through diode 102. When a voltage level applied to the drain terminal is higher than a voltage level applied to the source terminal of HEMT 100 and HEMT 100 is turned off, diode 102 may be reversely biased to prevent a current from flowing from the drain terminal to the source terminal of HEMT 100 through diode 102. When the reverse bias voltage applied to diode 102 is greater than the avalanche breakdown voltage of diode 102 while HEMT 100 is turned off, diode 102 may experience avalanche breakdown, where a high current may flow from the drain terminal of HEMT 100 to the source terminal of HEMT 100 through diode 102, and the voltage difference between the drain terminal and the source terminal of HEMT 100 may be clamped at about the avalanche breakdown voltage of diode 102. The breakdown voltage of HEMT 100 may be higher than the avalanche breakdown voltage of diode 102, and thus the voltage applied across HEMT 100 may not reach the breakdown voltage of HEMT 100 to cause damages to HEMT 100. Diode 102 may stop conducting when the voltage difference between the drain terminal and the source terminal of HEMT 100 is lower than the avalanche breakdown voltage of diode 102. As such, the reversible avalanche breakdown of diode 102 may protect HEMT 100 from a high voltage and/or current surge. As explained above, it is advantageous to integrate HEMT 100 and diode 102 on a same semiconductor die to reduce the parasitic inductance, resistance, and/or capacitance of the interconnects between HEMT 100 and diode 102, which can reduce the device's response time to facilitate high-speed switching applications. Integrating HEMT 100 and diode 102 on a same semiconductor die can also reduce the overall cost and the overall size of the device.

According to certain examples, a semiconductor device may include a substrate, a semiconductor layer stack on the substrate, and a gate, a source, and a drain formed on or in the semiconductor layer stack. The semiconductor layer stack may include an HEMT formed by a non-silicon channel layer and a barrier layer on the channel layer. At least one of the substrate or the semiconductor layer stack may include a diode formed therein, where a first terminal of the diode may be electrically coupled to the source, and a second terminal of the diode may be electrically coupled to the drain. The diode may function as an avalanche diode having the recoverable breakdown capability to protect the semiconductor device against high voltages and/or high currents. The substrate may include, for example, silicon, silicon carbide, SOI, sapphire, GaN, engineered GaN, or another semiconductor material having a bandgap wider than the bandgap of silicon. The channel layer may include, for example, GaN, AlGaN, or InAlN.

In some examples, the diode may be formed in the substrate. For example, the diode may be a vertical diode formed by a p-doped semiconductor layer and an n-doped semiconductor layer in the substrate, or may be a lateral diode formed by a doped semiconductor layer and an oppositely doped semiconductor region in the doped semiconductor layer. In some examples, the diode may be formed in the semiconductor layer stack, such as a vertical diode formed by a p-doped semiconductor layer and an n-doped semiconductor layer in the semiconductor layer stack. The doped semiconductor layer(s) may be formed in the substrate or the semiconductor layer stack by, for example, epitaxial growth and/or ion implantation. The doped semiconductor region may be formed by, for example, ion implantation in a selected region of a doped semiconductor layer. In some examples, the diode may be a Schottky diode formed by a semiconductor layer and a Schottky metal contact.

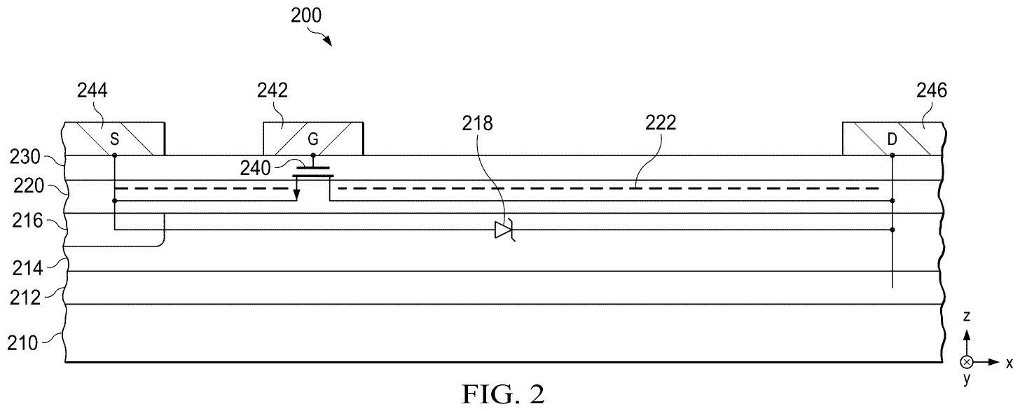

FIG. 2 is a cross-sectional view of an example of a semiconductor device 200 including an HEMT 240 and a diode on a same semiconductor die. In the illustrated example, semiconductor device 200 includes a substrate 210, a semiconductor layer stack that includes at least a channel layer 220 and a barrier layer 230, and a diode 218 formed in substrate 210 or the semiconductor layer stack. HEMT 240 may be formed by channel layer 220, barrier layer 230, a gate structure 242, a source structure 244, and a drain structure 246. HEMT 240 can be an example of HEMT 100 of FIG. 1B, and diode 218 can be an example of diode 102 of FIG. 1B.

Source structure 244 may be electrically coupled to the anode of diode 218 through a low resistance and low inductance connection, while drain structure 246 may be electrically coupled to the cathode of diode 218 through a low resistance and low inductance connection. Channel layer 220 of HEMT 240 may include a non-silicon material, such as GaN, AlGaN, or InAlN. In one example, channel layer 220 may include undoped GaN, and barrier layer 230 may include AlGaN. Channel layer 220 and barrier layer 230 may form a heterostructure that may induce a 2DEG 222 near the interface between channel layer 220 and barrier layer 230 due to the different energy band structures of channel layer 220 and barrier layer 230. HEMT 240 may be an enhancement mode high electron mobility transistor or a depletion mode high electron mobility transistor. For example, gate structure 242 may be similar to the gate structure of HEMT 100, such that HEMT 240 may be an enhancement mode high electron mobility transistor.

Substrate 210 may be similar to substrate 110, and may include, for example, a silicon substrate, a silicon carbide substrate, an SOI substrate, a sapphire substrate, a GaN substrate, a GaAs substrate, an engineered GaN substrate (a QST substrate), a substrate including another semiconductor material that has a bandgap wider than the bandgap of silicon, or any other suitable substrate. In one example, substrate 210 may include a bulk silicon substrate, and may include one or more transition layers or buffer layers of suitable materials for accommodating the lattice mismatch between the silicon substrate and channel layer 220 as described above with respect to, for example, FIG. 1A.

Diode 218 may be in either substrate 210 or the semiconductor layer stack, and may include either a lateral diode or a vertical diode. In some examples, diode 218 may be a silicon diode. In some examples, diode 218 may be a diode formed by GaN-based materials. A first terminal (e.g., anode) of diode 218 may be electrically coupled to source structure 244 of HEMT 240, while a second terminal (e.g., cathode) of diode 218 may be electrically coupled to drain structure 246 of HEMT 240. In some examples, diode 218 may be formed by a p-doped semiconductor layer (or a region of a semiconductor layer) and an n-doped semiconductor layer (or a region of a semiconductor layer). The materials, the doping densities, and/or the dimensions of the semiconductor layers (or regions) may be selected such that diode 218 may have the desired avalanche breakdown voltage, such as equal to or greater than the voltage rating of semiconductor device 200 but lower than the breakdown voltage of HEMT 240. As such, diode 218 may protect HEMT 240 against an irreversible catastrophic breakdown under high reverse bias voltages.

In some examples, substrate 210 may include a first semiconductor layer 212 (e.g., an n⁺-type semiconductor layer such as an n⁺-doped silicon layer, or a p⁺-type semiconductor layer such as a p⁺-doped silicon layer) and a second semiconductor layer 214 (e.g., a p-type semiconductor layer such as a p-doped silicon layer, or an n-type semiconductor layer such as an n-doped silicon layer) that form diode 218, where diode 218 may be a vertical diode (e.g., having a p-n junction along the z-axis of FIG. 2). In some examples, a heavily doped region 216 may be formed in second semiconductor layer 214, and may be used to form a low-resistance contact between source structure 244 and second semiconductor layer 214. In some examples, first semiconductor layer 212 may be the anode of diode 218, while second semiconductor layer 214 may be the cathode of diode 218. In some examples, first semiconductor layer 212 may be the cathode of diode 218, while second semiconductor layer 214 may be the anode of diode 218.

In some examples, diode 218 may be a lateral diode (e.g., having a p-n junction along the x and/or y axis of FIG. 2) formed in second semiconductor layer 214 (e.g., n-doped or p-doped silicon layer) that includes an oppositely doped region and/or a region heavily doped with the same type of dopants as second semiconductor layer 214. In one example, second semiconductor layer 214 may include a p-doped semiconductor layer, and an n⁺-doped region may be formed in second semiconductor layer 214 to form the lateral diode with second semiconductor layer 214. In another example, second semiconductor layer 214 may include an n-doped semiconductor layer, and a p⁺-doped region may be formed in second semiconductor layer 214 to form the lateral diode with second semiconductor layer 214.

In some examples, first semiconductor layer 212 and second semiconductor layer 214 may be parts of the semiconductor layer stack, and may include doped epitaxial layers (e.g., GaN layers) grown on substrate 210 to form a vertical GaN-based diode. In one example, first semiconductor layer 212 may be a p⁺-doped GaN layer, and second semiconductor layer 214 may be an n-doped GaN layer. In one example, first semiconductor layer 212 may be an n⁺-doped GaN layer, and second semiconductor layer 214 may be a p-doped GaN layer. In one example, first semiconductor layer 212 may be a p-doped GaN layer, and second semiconductor layer 214 may be an n⁺-doped GaN layer. In another example, first semiconductor layer 212 may be an n-doped GaN layer, and second semiconductor layer 214 may be a p⁺-doped GaN layer.

The semiconductor device including an HEMT and a monolithically integrated diode disclosed herein may have avalanche capability for high voltage/current surge protection and may be used in applications where repetitive avalanche breakdown is needed, such as in some automotive electric control units. Compared with devices including a board-level or package-level integrated avalanche diode, the semiconductor device disclosed herein may have much lower parasitic resistance and inductance due to the monolithic integration. Therefore, the device may have shorter response time during switching, and may be more suitable for high-speed switching. The avalanche breakdown voltage or energy level of the avalanche diode can be tuned by, for example, tuning the doping densities or doping profiles of the two terminals of the diode, and/or the dimensions of the two terminals of the diode, such as the thickness of a lightly doped semiconductor layer of the diode. Because no additional packaging or board-level bonding processes are needed (e.g., to connect an HEMT to an off-chip diode), the cost of fabricating the devices may be lower.

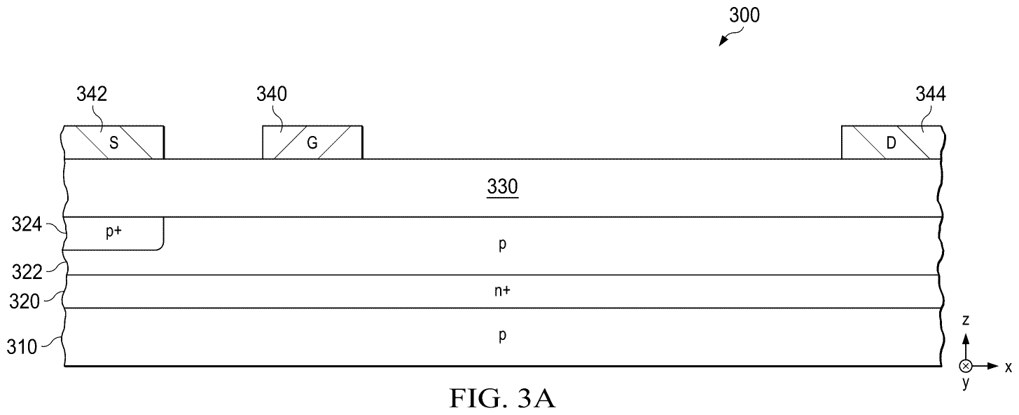

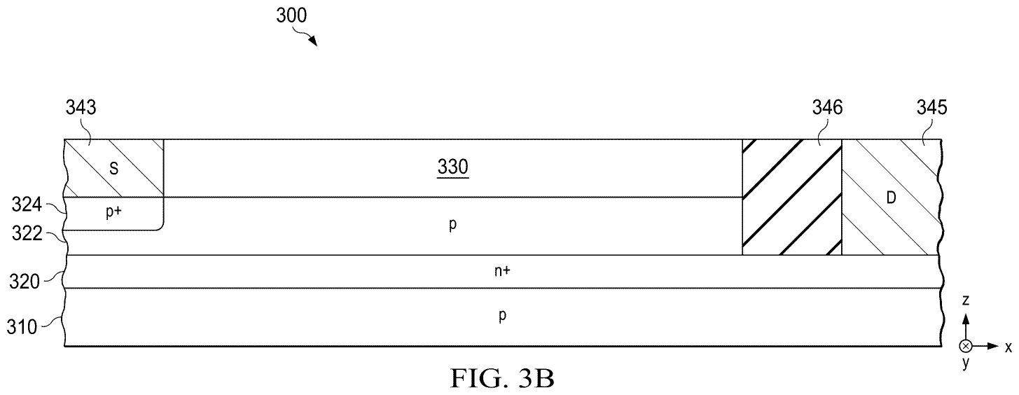

FIGS. 3A and 3B are cross-sectional views of an example of a semiconductor device 300 including an HEMT and a diode on a same semiconductor die. In the illustrated example, semiconductor device 300 includes a substrate that includes a high-resistivity silicon substrate 310, an n⁺-doped silicon layer 320, and a p-doped silicon layer 322. In some examples, silicon substrate 310 may be undoped or lightly p-doped. The high-resistivity silicon substrate 310 can be part of a reduced surface field (RESURF) structure that can result in a higher avalanche breakdown voltage. A vertical diode may be formed by n⁺-doped silicon layer 320 and p-doped silicon layer 322. The doping densities, doping profiles, and/or thicknesses of n⁺-doped silicon layer 320 and p-doped silicon layer 322 can be selected to achieve the desired avalanche breakdown voltage of the vertical silicon diode. In some examples, a p⁺-doped region 324 may be formed in p-doped silicon layer 322 to reduce a contact resistance with p-doped silicon layer 322.

A semiconductor layer stack 330 may be formed on the substrate by, for example, epitaxial growth. Semiconductor layer stack 330 may include at least a channel layer and a barrier layer that may form a heterostructure with a 2DEG channel at the interface of the heterostructure. For example, the channel layer may include GaN, and the barrier layer may include AlGaN. A gate structure 340, a source structure 342, and a drain structure 344 may then be formed on or in semiconductor layer stack 330 to form the HEMT that includes the channel layer and the barrier layer.

As described above, in some examples, gate structure 340 may include a gate electrical contact (a metal electrode) over the barrier layer, and the HEMT may be a depletion mode high electron mobility transistor. In some examples, gate structure 340 may include a p-doped semiconductor layer (e.g., a p-GaN layer) formed on the barrier layer and a gate electrical contact formed on the p-doped semiconductor layer, and the HEMT may be an enhancement mode high electron mobility transistor.

Source structure 342 may be formed on and/or in semiconductor layer stack 330, and may be electrically coupled to the channel layer through physical contact or tunneling effect. Source structure 342 may include or may be electrically coupled to at least one source deep contact 343 formed at one or more regions of semiconductor device 300 and extending through semiconductor layer stack 330 to contact p⁺-doped region 324. Thus, source structure 342 may be electrically coupled to p-doped silicon layer 322 through at least one source deep contact 343 and p⁺-doped region 324 in p-doped silicon layer 322, such that the resistance between source structure 342 and p-doped silicon layer 322 of the diode may be low.

Drain structure 344 may also be formed on and/or in semiconductor layer stack 330, and may be electrically coupled to the channel layer through physical contact or through tunneling effect. Drain structure 344 may include or may be electrically coupled to at least one drain deep contact 345 formed at one or more regions of semiconductor device 300 and extending through semiconductor layer stack 330 and p-doped silicon layer 322 to contact n⁺-doped silicon layer 320 of the diode. Drain deep contact 345 may be surrounded by an isolation layer 346 to isolate drain deep contact 345 from p-doped silicon layer 322, such that drain structure 344 may be electrically coupled to n⁺-doped silicon layer 320 of the diode, whereas source structure 342 may be electrically coupled to p-doped silicon layer 322 of the diode. Isolation layer 346 may include a dielectric material such as silicon dioxide, silicon nitride, aluminum oxide, and the like.

As described above, the gate electrical contact of gate structure 340, source structure 342, source deep contact 343, drain structure 344, and drain deep contact 345 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 340, source structure 342, source deep contact 343, drain structure 344, and drain deep contact 345.

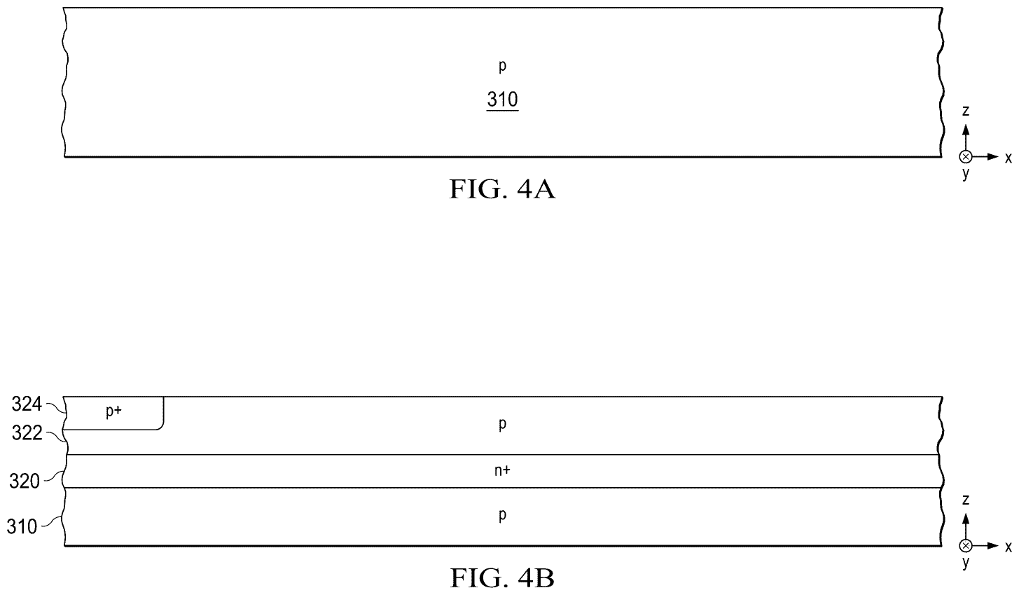

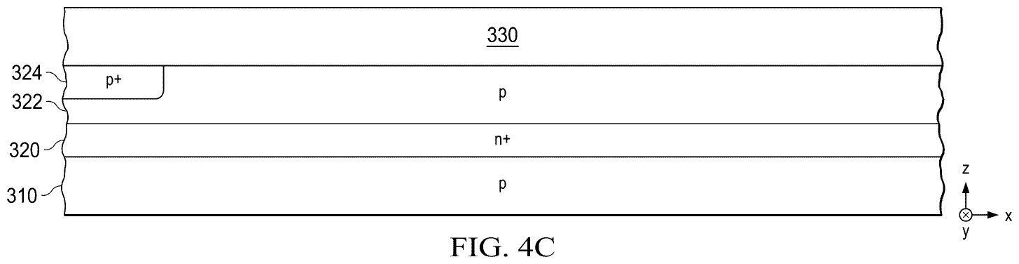

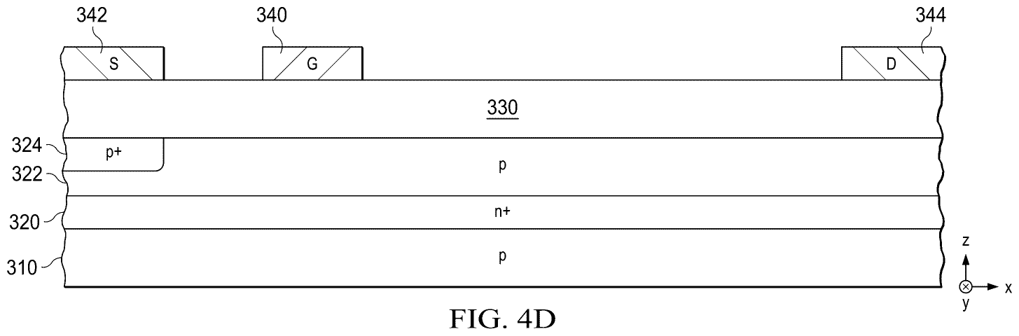

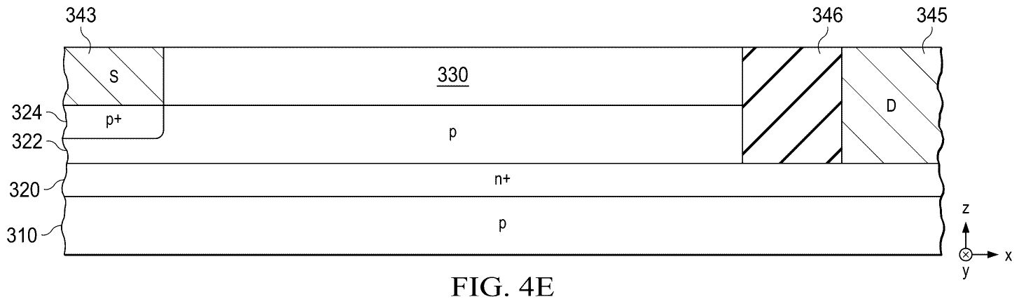

FIGS. 4A-4E illustrate an example of a process of fabricating a semiconductor device such as semiconductor device 300 of FIGS. 3A and 3B. FIG. 4A shows high-resistivity silicon substrate 310, which may be undoped or lightly doped with a p-type dopant and thus may have a high resistivity. The p-type dopant may include, for example, one or more Group III elements, such as boron (B), aluminum (Al), gallium (Ga), indium (In), and the like.

As shown in FIG. 4B, n⁺-doped silicon layer 320 may be formed in silicon substrate 310 through, for example, n⁺ ion implantation (e.g., using an ion beam) and dopant activation. In some examples, n⁺-doped silicon layer 320 may be an n⁺ buried layer (NBL) formed by doping silicon substrate 310 with an n-type dopant that may be a heavy atom and resistant to diffusion during subsequent high-temperature process, or any other methods for forming an NBL layer. The n-type dopant may include, for example, one or more Group V elements, such as phosphorus (P), arsenic (As), antimony (Sb), and the like. After forming n⁺-doped silicon layer 320 in silicon substrate 310, p-type ion implantation and dopant activation may be performed to change a top layer of n⁺-doped silicon layer 320 into p-doped silicon layer 322. The p-type dopant may include, for example, B, Al, Ga, In, and the like. A vertical silicon diode may thus be formed by p-doped silicon layer 322 and the underlying n⁺-doped silicon layer 320. The doping densities, doping profiles, and thicknesses of n⁺-doped silicon layer 320 and p-doped silicon layer 322 can be tuned to achieve the desired avalanche breakdown voltage of the vertical silicon diode. For example, the avalanche breakdown voltage of the vertical silicon diode may increase when the doping density of n⁺-doped silicon layer 320 or p-doped silicon layer 322 is decreased and/or when the thickness of p-doped silicon layer 322 is increased. A region of p-doped silicon layer 322 may be heavily doped with the p-type dopant to form p⁺-doped region 324, thereby reducing the contact resistance with p-doped silicon layer 322.

FIG. 4C shows that semiconductor layer stack 330 may be formed on silicon substrate 310 that includes the vertical silicon diode formed therein. Semiconductor layer stack 330 may be formed by, for example, epitaxially growing the channel layer (e.g., a GaN layer) of the HEMT and then epitaxially growing the barrier layer (e.g., an AlGaN layer) of the HEMT on the channel layer. In some examples, one or more buffer layers may be grown on silicon substrate 310 before growing the channel layer. The epitaxial layers of semiconductor layer stack 330 may be grown using, for example, vapor-phase epitaxy (VPE), liquid-phase epitaxy (LPE), molecular beam epitaxy (MBE), or metalorganic chemical vapor deposition (MOCVD).

As shown in FIG. 4D, gate structure 340, source structure 342, and drain structure 344 of the HEMT may be formed on and/or in semiconductor layer stack 330. As described above, in some examples, gate structure 340 may include a p-doped semiconductor layer (e.g., a p-GaN layer) formed on the barrier layer and a gate electrical contact formed on the p-doped semiconductor layer, such that the HEMT may be an enhancement mode HEMT. In some examples, gate structure 340 may include a gate electrical contact (a metal electrode) formed over the barrier layer, and the HEMT may be a depletion mode HEMT. Source structure 342 and drain structure 344 may be formed on and/or in semiconductor layer stack 330, and may be electrically coupled to the channel layer of the HEMT through physical contact or tunneling effect. As described above, gate structure 340, source structure 342, and drain structure 344 may include, for example, Cu, W, Au, Al, Ti, Ni, Pt, a metal alloy, or a combination thereof.

FIG. 4E shows that at least one source deep contact 343 may be formed to electrically couple source structure 342 to the anode (e.g., p-doped silicon layer 322) of the silicon diode formed in silicon substrate 310. Source deep contact 343 may extent through semiconductor layer stack 330 to form a low-resistance metal-semiconductor contact with p⁺-doped region 324 of p-doped silicon layer 322. At least one drain deep contact 345 may be formed to stack to the cathode (e.g., n⁺-doped silicon layer 320) of the silicon diode formed in silicon substrate 310. Drain deep contact 345 may extent through semiconductor layer stack 330 and p-doped silicon layer 322 to form a low-resistance metal-semiconductor contact with n⁺-doped silicon layer 320. Isolation layer 346 may be formed in semiconductor layer stack 330 and p-doped silicon layer 322 to electrically isolate drain deep contact 345 from at least p-doped silicon layer 322. In one example, semiconductor layer stack 330 and p-doped silicon layer 322 may be etched at the drain region to form one or more trenches, a dielectric material may be deposited to fill the one or more trenches, the dielectric material in the center region of each trench may be removed to form a hole surrounded by isolation layer 346, and a metal material may be deposited into the hole to form a drain deep contact 345 that is surrounded by isolation layer 346.

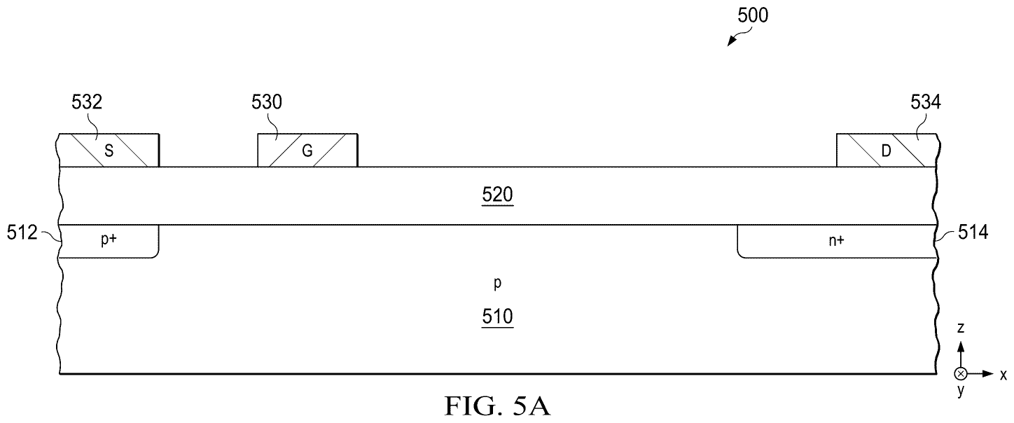

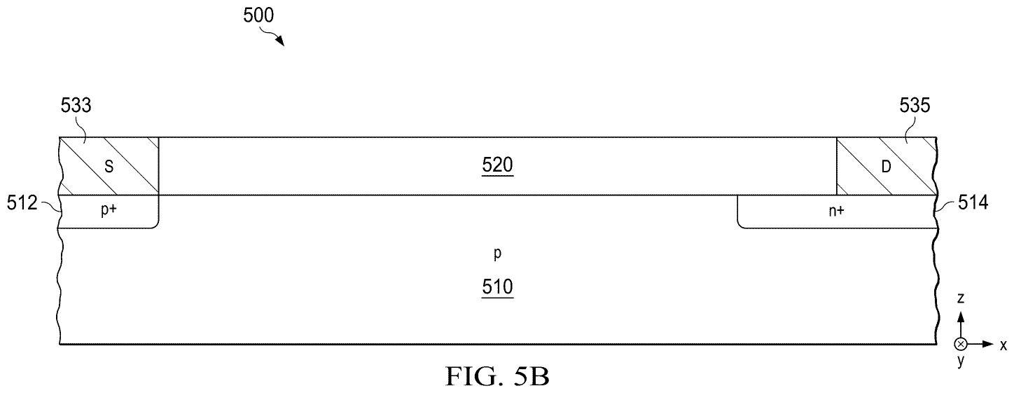

FIGS. 5A and 5B are cross-sectional views of an example of a semiconductor device 500 including an HEMT and a diode on a same semiconductor die. In the illustrated example, semiconductor device 500 includes a substrate that includes a high-resistivity p-type silicon substrate 510, and a p⁺-doped region 512 and an n⁺-doped region 514 formed in p-type silicon substrate 510. A lateral silicon diode may be formed by p-type silicon substrate 510 and n⁺-doped region 514. The doping densities and doping profiles of p-type silicon substrate 510 and n+-doped region 514 may be selected to achieve the desired avalanche breakdown voltage of the lateral silicon diode.

A semiconductor layer stack 520 may be formed on p-type silicon substrate 510 by, for example, epitaxial growth. Semiconductor layer stack 520 may include at least a channel layer and a barrier layer that may form a heterostructure with a 2DEG channel at the interface of the heterostructure. For example, the channel layer may include GaN, and the barrier layer may include AlGaN. A gate structure 530, a source structure 532, and a drain structure 534 may then be formed on or in semiconductor layer stack 520 to form the HEMT that includes the channel layer and the barrier layer.

As described above, in some examples, gate structure 530 may include a gate electrical contact (a metal electrode) over the barrier layer, and the HEMT may be a depletion mode high electron mobility transistor. In some examples, gate structure 530 may include a p-doped semiconductor layer (e.g., a p-GaN layer) formed on the barrier layer and a gate electrical contact formed on the p-doped semiconductor layer, and the HEMT may be an enhancement mode high electron mobility transistor.

Source structure 532 may be formed on and/or in semiconductor layer stack 520, and may be electrically coupled to the channel layer through physical contact or tunneling effect. Source structure 532 may include or may be electrically coupled to at least one source deep contact 533 formed at one or more regions of semiconductor device 500 and extending through semiconductor layer stack 520 to contact p⁺-doped region 512. Thus, source structure 532 may be electrically coupled to p-type silicon substrate 510 through at least one source deep contact 533 and p⁺-doped region 512 in p-type silicon substrate 510, such that the resistance between source structure 532 and p-type silicon substrate 510 of the lateral silicon diode may be low.

Drain structure 534 may also be formed on and/or in semiconductor layer stack 520, and may be electrically coupled to the channel layer through physical contact or through tunneling effect. Drain structure 534 may include or may be electrically coupled to at least one drain deep contact 535 formed at one or more regions of semiconductor device 500 and extending through semiconductor layer stack 520 to contact n⁺-doped region 514 of the lateral silicon diode, such that the resistance between drain structure 534 and n⁺-doped region 514 of the lateral silicon diode may be small.

As described above, the gate electrical contact of gate structure 530, source structure 532, source deep contact 533, drain structure 534, and drain deep contact 535 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 530, source structure 532, source deep contact 533, drain structure 534, and drain deep contact 535. In semiconductor device 500, source deep contact 533 and drain deep contact 535 may have the same depth, and may be fabricated using the same processes.

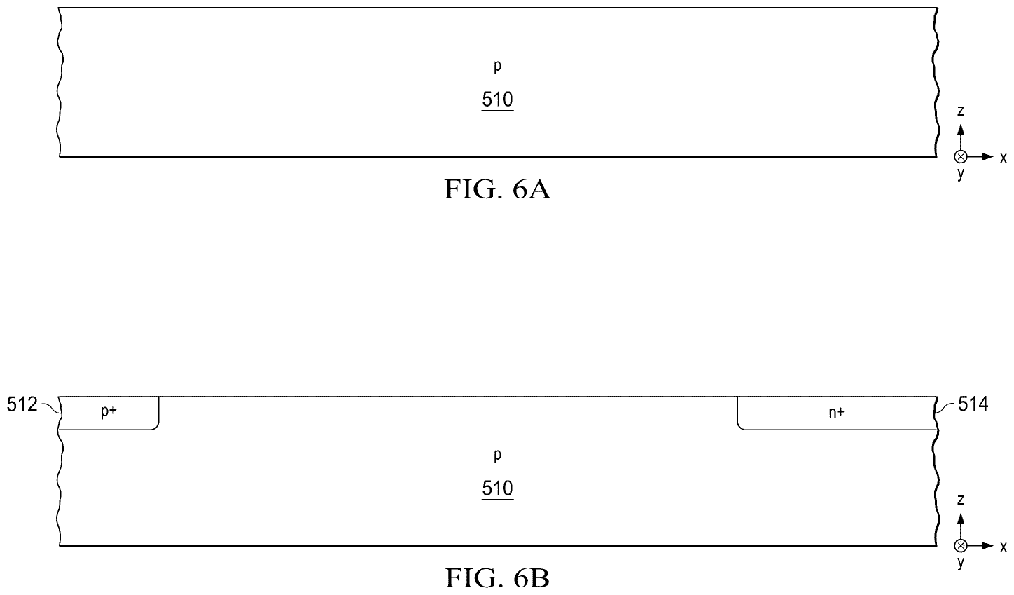

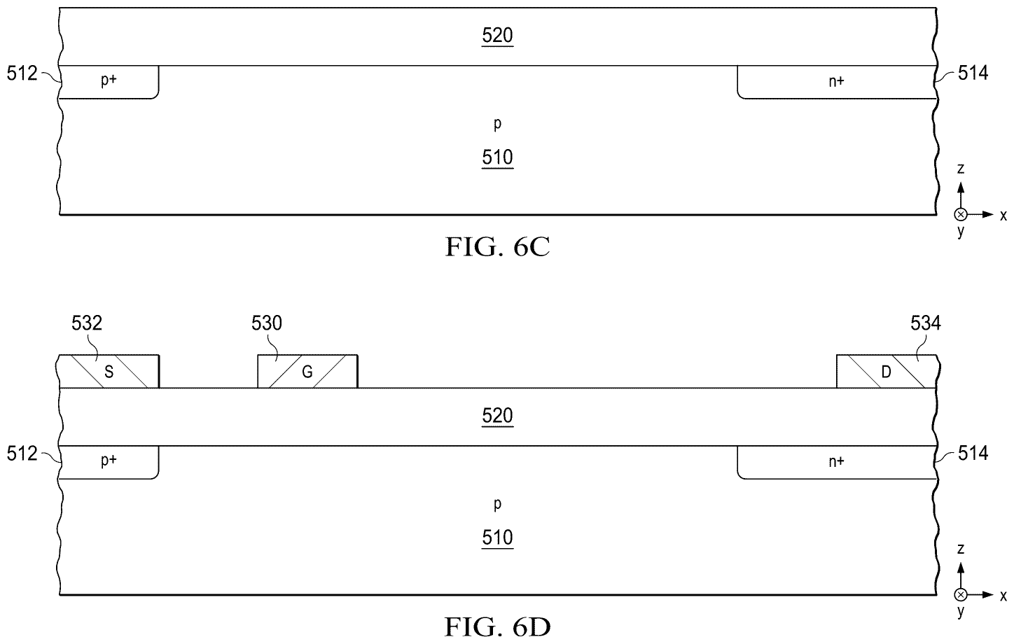

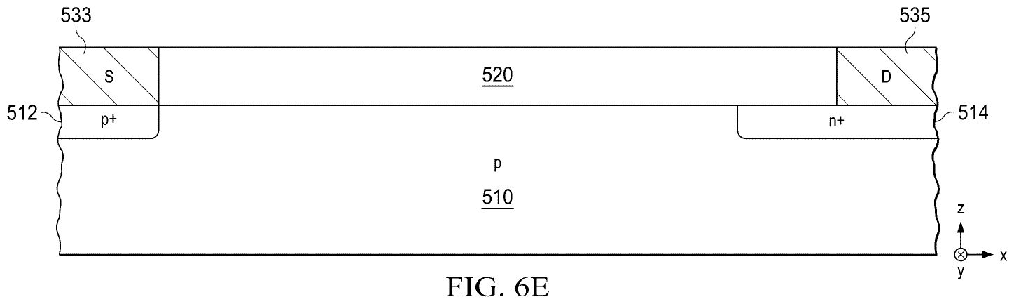

FIGS. 6A-6E illustrate an example of a process of fabricating a semiconductor device such as semiconductor device 500 of FIGS. 5A and 5B. FIG. 6A shows p-type silicon substrate 510, which may be formed by doping a silicon substrate with a p-type dopant, such as B, Al, Ga, In, and the like. As shown in FIG. 6B, a first region of p-type silicon substrate 510 may be heavily doped with a p-type dopant (e.g., B, Al, Ga, In, etc.) to form p⁺-doped region 512, and a second region of p-type silicon substrate 510 may be heavily doped with an n-type dopant (e.g., P, As, Sb, etc.) to form n⁺-doped region 514 in p-type silicon substrate 510. In one example, p⁺-doped region 512 and n⁺-doped region 514 may each be formed by ion implantation and dopant activation processes. A lateral silicon diode may be formed by p-type silicon substrate 510 and n⁺-doped region 514. The doping densities and doping profiles of n⁺-doped region 514 and p-type silicon substrate 510 can be selected to achieve the desired avalanche breakdown voltage of the lateral silicon diode. For example, the avalanche breakdown voltage of the lateral silicon diode may increase when the doping density of n⁺-doped region 514 or p-type silicon substrate 510 is decreased.

FIG. 6C shows that semiconductor layer stack 520 may be formed on p-type silicon substrate 510 that includes the lateral silicon diode formed therein. Semiconductor layer stack 520 may be formed by, for example, epitaxially growing the channel layer (e.g., a GaN layer) of the HEMT and then epitaxially growing the barrier layer (e.g., an AlGaN layer) of the HEMT on the channel layer. In some examples, one or more buffer layers may be grown on p-type silicon substrate 510 before growing the channel layer. The epitaxial layers of semiconductor layer stack 520 may be grown using, for example, VPE, LPE, MBE, or MOCVD.

As shown in FIG. 6D, gate structure 530, source structure 532, and drain structure 534 of the HEMT may be formed on and/or in semiconductor layer stack 520. As described above, in some examples, gate structure 530 may include a p-doped semiconductor layer (e.g., a p-GaN layer) formed on the barrier layer and a gate electrical contact formed on the p-doped semiconductor layer, such that the HEMT may be an enhancement mode HEMT. In some examples, gate structure 530 may include a gate electrical contact (a metal electrode) formed over the barrier layer, and the HEMT may be a depletion mode HEMT. Source structure 532 and drain structure 534 may be formed on and/or in semiconductor layer stack 520, and may be electrically coupled to the channel layer of the HEMT through physical contact or tunneling effect. As described above, gate structure 530, source structure 532, and drain structure 534 may include a metal material, such as Cu, W, Au, Al, Ti, Ni, Pt, a metal alloy, or a combination thereof.

FIG. 6E shows that at least one source deep contact 533 may be formed to electrically couple source structure 532 to the anode (e.g., p-type silicon substrate 510) of the silicon diode. Source deep contact 533 may extent through semiconductor layer stack 520 to form a low-resistance metal-semiconductor contact with p⁺-doped region 512 of p-type silicon substrate 510. At least one drain deep contact 535 may be formed to electrically couple drain structure 534 to the cathode (e.g., n⁺-doped region 514) of the silicon diode formed in p-type silicon substrate 510. Drain deep contact 535 may extent through semiconductor layer stack 520 to form a low-resistance metal-semiconductor contact with n⁺-doped region 514. Source deep contact 533 and drain deep contact 535 may be formed using the same fabrication processes, such as semiconductor etching and metal deposition, at least because both contacts penetrate through the same thickness of semiconductor layer stack 520.

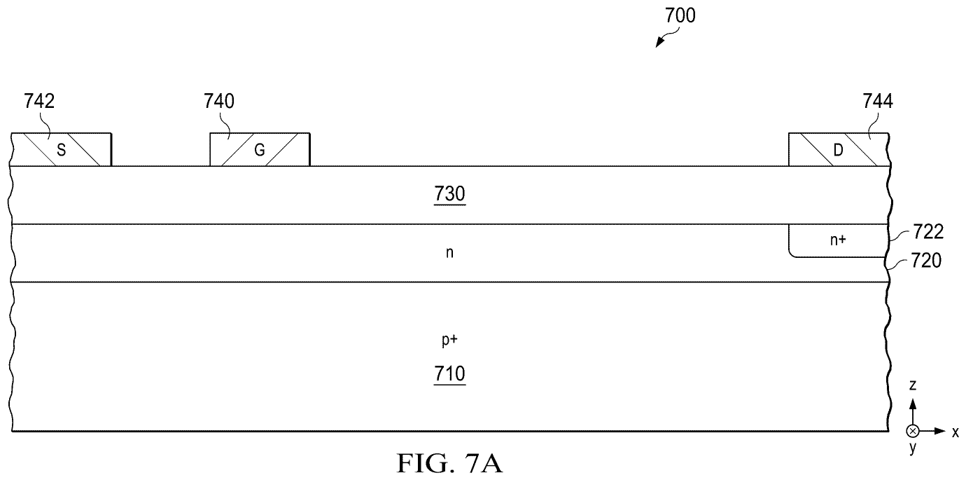

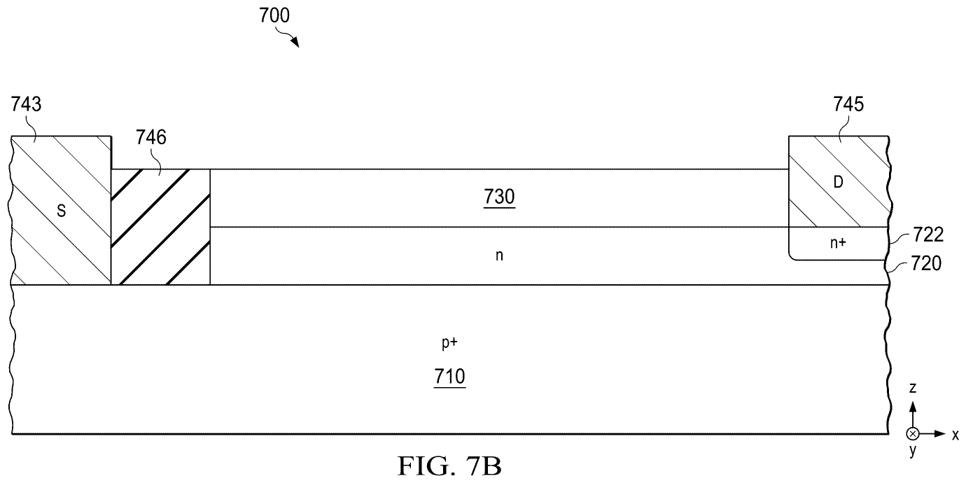

FIGS. 7A and 7B are cross-sectional views of an example of a semiconductor device 700 including an HEMT and a diode on a same semiconductor die. In the illustrated example, semiconductor device 700 may include a substrate that includes a low-resistivity silicon substrate 710 and an n-doped silicon layer 720. Low-resistivity silicon substrate 710 may be heavily p-doped. In some examples, n-doped silicon layer 720 may be epitaxially grown on low-resistivity silicon substrate 710, and may be lightly doped. The n-doped silicon layer 720 may have a high resistivity compared with silicon substrate 710. In some examples, n-doped silicon layer 720 may include a n⁺-doped region 722. A vertical diode may be formed by n-doped silicon layer 720 and the heavily p-doped low-resistivity silicon substrate 710. The doping densities and doping profiles of n-doped silicon layer 720 and p⁺-doped low-resistivity silicon substrate 710 and/or the thickness of n-doped silicon layer 720 can be selected to achieve the desired avalanche breakdown voltage of the vertical silicon diode.

A semiconductor layer stack 730 may be formed on the substrate by, for example, epitaxial growth. Semiconductor layer stack 730 may include at least a channel layer and a barrier layer that may form a heterostructure with a 2DEG channel at the interface of the heterostructure. For example, the channel layer may include GaN, and the barrier layer may include AlGaN. A gate structure 740, a source structure 742, and a drain structure 744 may then be formed on or in semiconductor layer stack 730 to form the HEMT that includes the channel layer and the barrier layer. The vertical electric field in semiconductor layer stack 730 (e.g., during avalanche breakdown) can be reduced due to a larger voltage sustained by the reverse-biased p-n junction between p⁺-doped low-resistivity silicon substrate 710 and n-doped silicon layer 720.

In some examples, gate structure 740 may include a gate electrical contact (a metal electrode) over the barrier layer, and the HEMT may be a depletion mode high electron mobility transistor. In some examples, gate structure 740 may include a p-doped semiconductor layer (e.g., a p-GaN layer) formed on the barrier layer and a gate electrical contact formed on the p-doped semiconductor layer, and the HEMT may be an enhancement mode high electron mobility transistor.

Source structure 742 may be formed on and/or in semiconductor layer stack 730, and may be electrically coupled to the channel layer of the HEMT through physical contact or tunneling effect. Source structure 742 may include or may be electrically coupled to at least one source deep contact 743 formed at one or more regions of semiconductor device 700 and extending through semiconductor layer stack 730 and n-doped silicon layer 720 to contact p⁺-doped low-resistivity silicon substrate 710. Thus, source structure 742 may be electrically coupled to p⁺-doped low-resistivity silicon substrate 710 through at least one source deep contact 743. Source deep contact 743 may be surrounded by an isolation layer 746 to isolate source deep contact 743 from at least n-doped silicon layer 720. Isolation layer 746 may include a dielectric material such as silicon dioxide, silicon nitride, aluminum oxide, and the like.

Drain structure 744 may also be formed on and/or in semiconductor layer stack 730, and may be electrically coupled to the channel layer through physical contact or through tunneling effect. Drain structure 744 may include or may be electrically coupled to at least one drain deep contact 745 formed at one or more regions of semiconductor device 700 and extending through semiconductor layer stack 730 to contact n⁺-doped region 722 in n-doped silicon layer 720, such that the contact resistance between drain structure 744 and n-doped silicon layer 720 of the diode may be small.

The gate electrical contact of gate structure 740, source structure 742, source deep contact 743, drain structure 744, and drain deep contact 745 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 740, source structure 742, source deep contact 743, drain structure 744, and drain deep contact 745.

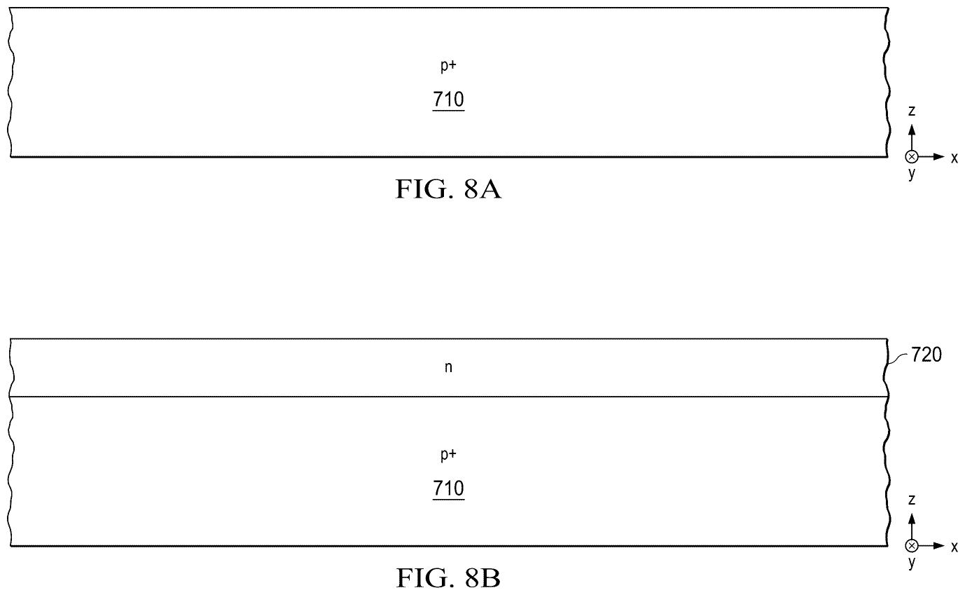

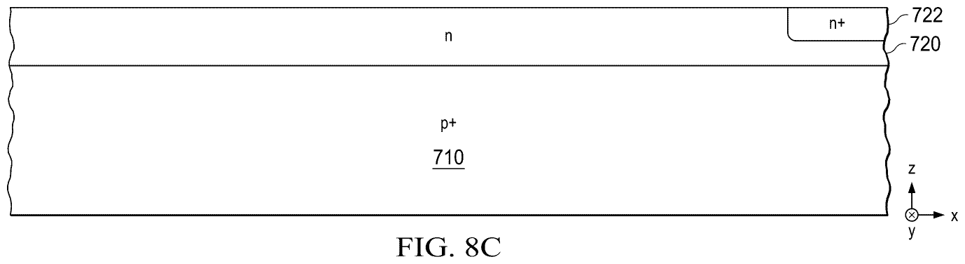

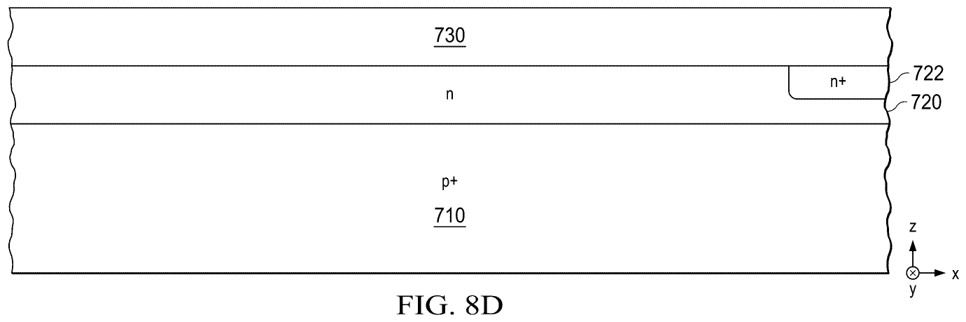

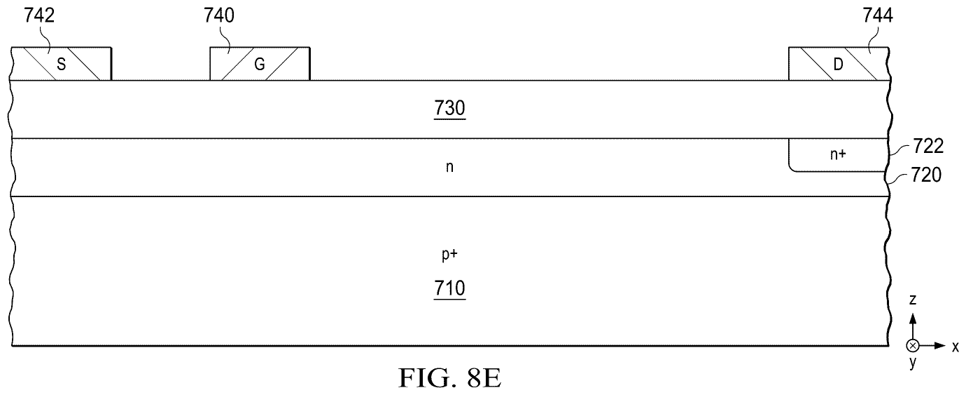

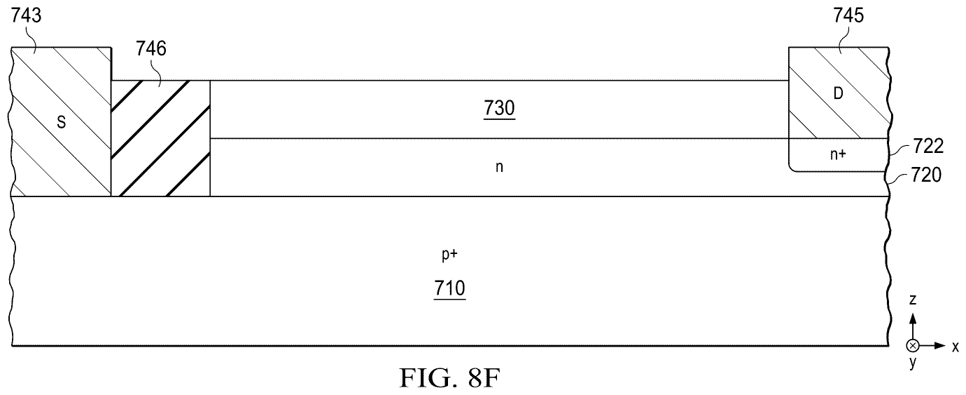

FIGS. 8A-8F illustrate an example of a process of fabricating a semiconductor device such as semiconductor device 700 of FIGS. 7A and 7B. FIG. 8A shows low-resistivity silicon substrate 710, which may be heavily doped with a p-type dopant, such as B, Al, Ga, In, and the like. As shown in FIG. 8B, n-doped silicon layer 720 may be formed on silicon substrate 710 by, for example, epitaxial growth using, for example, VPE, LPE, MBE, or MOCVD. In some examples, the n-type dopant may be incorporated into n-doped silicon layer 720 during the epitaxial growth. In some examples, the n-type dopant may be implanted after the epitaxial growth to form the n-doped silicon layer 720. A vertical silicon diode may be formed by the heavily p⁺-doped silicon substrate 710 and n-doped silicon layer 720. The doping densities and doping profiles of silicon substrate 710 and n-doped silicon layer 720 and/or the thickness of n-doped silicon layer 720 can be tuned to achieve the desired avalanche breakdown voltage of the vertical silicon diode. In some examples, n⁺ ion implantation and dopant activation may be performed at a region of n-doped silicon layer 720 to form n⁺-doped region 722 as shown in FIG. 8C. The n-type dopant in n-doped silicon layer 720 and n⁺-doped region 722 may include, for example, P, As, Sb, and the like.

FIG. 8D shows that semiconductor layer stack 730 may be formed on silicon substrate 710 that includes the vertical silicon diode formed therein. Semiconductor layer stack 730 may be formed by, for example, epitaxially growing the channel layer (e.g., a GaN layer) of the HEMT and then epitaxially growing the barrier layer (e.g., an AlGaN layer) of the HEMT on the channel layer. In some examples, one or more buffer layers may be grown on n-doped silicon layer 720 before growing the channel layer. The epitaxial layers of semiconductor layer stack 730 may be grown using, for example, VPE, LPE, MBE, or MOCVD.

As shown in FIG. 8E, gate structure 740, source structure 742, and drain structure 744 of the HEMT may be formed on and/or in semiconductor layer stack 730. As described above, in some examples, gate structure 740 may include a p-doped semiconductor layer (e.g., a p-GaN layer) formed on the barrier layer and a gate electrical contact formed on the p-doped semiconductor layer, such that the HEMT may be an enhancement mode HEMT. In some examples, gate structure 740 may include a gate electrical contact (a metal electrode) formed over the barrier layer, and the HEMT may be a depletion mode HEMT. Source structure 742 and drain structure 744 may be formed on and/or in semiconductor layer stack 730, and may be electrically coupled to the channel layer of the HEMT through physical contact or tunneling effect. As described above, gate structure 740, source structure 742, and drain structure 744 may include, for example, Cu, W, Au, Al, Ti, Ni, Pt, a metal alloy, or a combination thereof.

FIG. 8F shows that at least one drain deep contact 745 may be formed to electrically couple drain structure 744 to the cathode (e.g., n-doped silicon layer 720) of the vertical silicon diode. Drain deep contact 745 may extent through semiconductor layer stack 730 to form a low-resistance metal-semiconductor contact with n⁺-doped region 722 of n-doped silicon layer 720. At least one source deep contact 743 may be formed to electrically couple source structure 742 to the anode (e.g., p⁺-doped low-resistivity silicon substrate 710) of the vertical silicon diode. Source deep contact 743 may extent through semiconductor layer stack 730 and n-doped silicon layer 720 to form a low-resistance metal-semiconductor contact with p+-doped low-resistivity silicon substrate 710. Isolation layer 746 may be formed in semiconductor layer stack 730 and n-doped silicon layer 720 to electrically isolate source deep contact 743 from at least n-doped silicon layer 720. In one example, semiconductor layer stack 730 and n-doped silicon layer 720 may be etched at the source region to form one or more trenches, a dielectric material may be deposited to fill the one or more trenches, the dielectric material in the center region of each trench may be removed to form a hole surrounded by isolation layer 746, and a metal material may be deposited into the hole to form a source deep contact 743 that is surrounded by isolation layer 746.

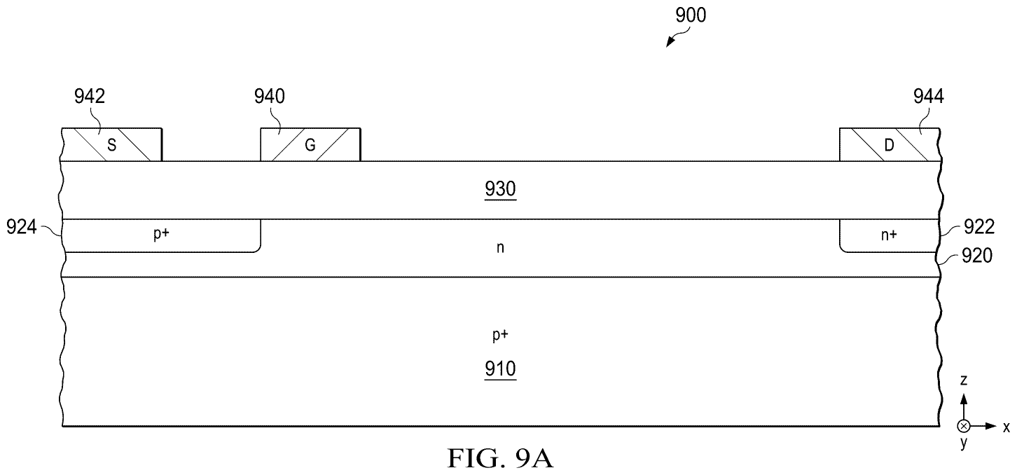

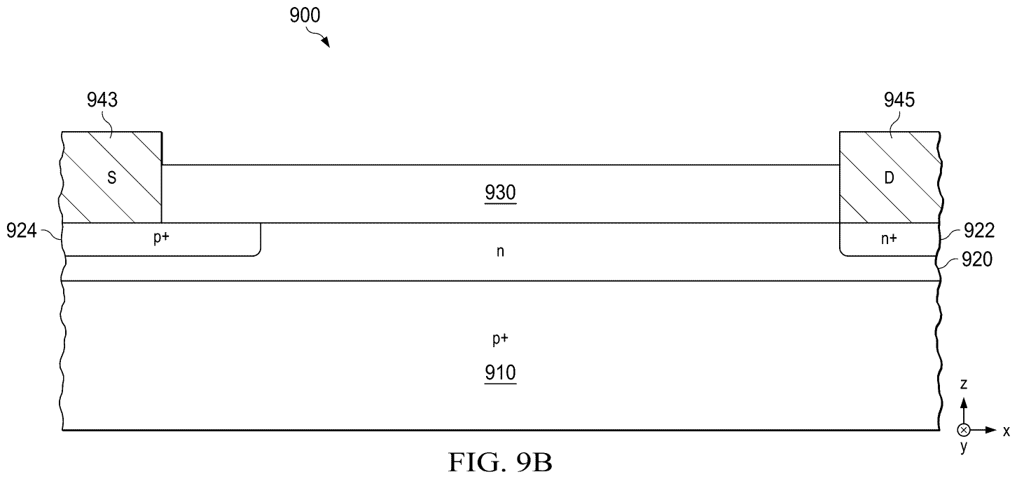

FIGS. 9A and 9B are cross-sectional views of an example of a semiconductor device 900 including an HEMT and a diode on a same semiconductor die. In the illustrated example, semiconductor device 900 includes a substrate that includes a low-resistivity silicon substrate 910 and an n-doped silicon layer 920. Low-resistivity silicon substrate 910 may be heavily doped with a p-type dopant. In some examples, n-doped silicon layer 920 may be epitaxially grown on low-resistivity silicon substrate 910, and may be lightly doped. In some examples, n-doped silicon layer 920 may include an n⁺-doped region 922 and a p⁺-doped region 924 formed therein. A lateral diode may be formed by p⁺-doped region 924 and n-doped silicon layer 920. In some examples, a vertical diode may be formed by n-doped silicon layer 920 and the p⁺-doped low-resistivity silicon substrate 910. The doping densities and doping profiles of n-doped silicon layer 920 and p⁺-doped region 924 (or p+-doped low-resistivity silicon substrate 910), and/or the thickness of n-doped silicon layer 920 can be selected to achieve the desired avalanche breakdown voltage of the silicon diode.

A semiconductor layer stack 930 may be formed on the substrate by, for example, epitaxial growth. Semiconductor layer stack 930 may include at least a channel layer and a barrier layer that may form a heterostructure with a 2DEG channel at the interface of the heterostructure. For example, the channel layer may include GaN, and the barrier layer may include AlGaN. A gate structure 940, a source structure 942, and a drain structure 944 may then be formed on or in semiconductor layer stack 930 to form the HEMT that includes the channel layer and the barrier layer.

In some examples, gate structure 940 may include a gate electrical contact (a metal electrode) over the barrier layer, and the HEMT may be a depletion mode high electron mobility transistor. In some examples, gate structure 940 may include a p-doped semiconductor layer (e.g., a p-GaN layer) formed on the barrier layer and a gate electrical contact formed on the p-doped semiconductor layer, and the HEMT may be an enhancement mode high electron mobility transistor.

Source structure 942 may be formed on and/or in semiconductor layer stack 930, and may be electrically coupled to the channel layer of the HEMT through physical contact or tunneling effect. Source structure 942 may include or may be electrically coupled to at least one source deep contact 943 formed at one or more regions of semiconductor device 900 and extending through semiconductor layer stack 930 to contact p⁺-doped region 924. Thus, source structure 942 may be electrically coupled to p⁺-doped region 924 through at least one source deep contact 943. In some examples, one or more source deep contacts may be formed to electrically couple source structure 942 to low-resistivity silicon substrate 910.

Drain structure 944 may also be formed on and/or in semiconductor layer stack 930, and may be electrically coupled to the channel layer of the HEMT through physical contact or through tunneling effect. Drain structure 944 may include or may be electrically coupled to at least one drain deep contact 945 formed at one or more regions of semiconductor device 900 and extending through semiconductor layer stack 930 to contact n⁺-doped region 922 in n-doped silicon layer 920, such that the resistance between drain structure 944 and n-doped silicon layer 920 of the diode may be small. In semiconductor device 900, source deep contact 943 and drain deep contact 945 may have the same depth (e.g., the thickness of semiconductor layer stack 930), and may be fabricated using the same processes.

The gate electrical contact of gate structure 940, source structure 942, source deep contact 943, drain structure 944, and drain deep contact 945 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 940, source structure 942, source deep contact 943, drain structure 944, and drain deep contact 945.

The example shown in FIGS. 9A and 9B may also include reduced surface field (RESURF) structure features that can result in higher avalanche breakdown voltage. In FIGS. 9A and 9B, when substrate 910 is a p⁺-doped low-resistivity substrate, and an n-type epitaxial layer (e.g., n-doped silicon layer 920) is grown on top of the substrate sequentially, substrate 910 can also be a RESURF structure when a certain thickness and doping of the n-doped silicon layer 920 are satisfied. The vertical depletion and lateral depletion may interact with each other to achieve more uniform electric field distribution so that the increase in surface field is slowed down with high voltage.

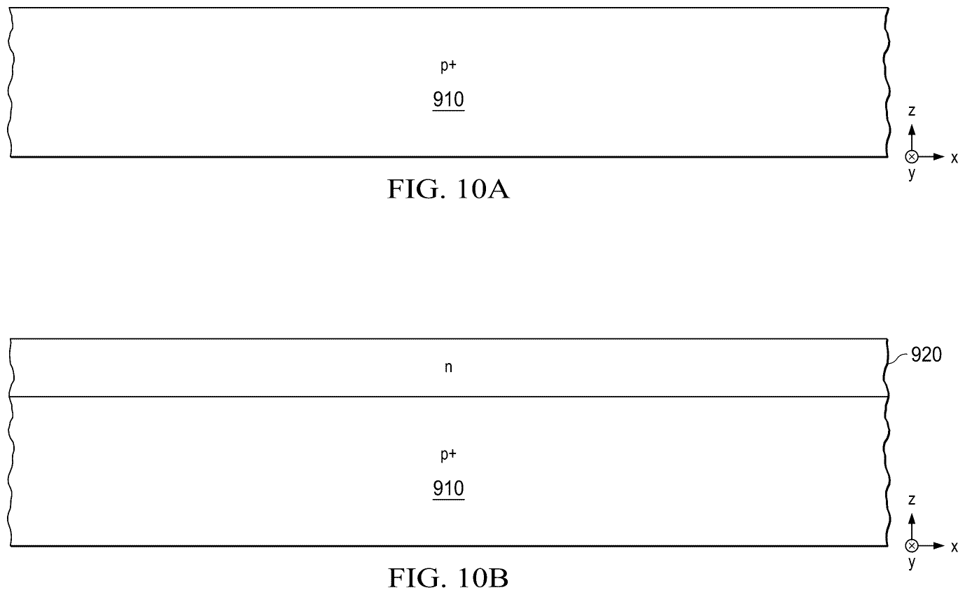

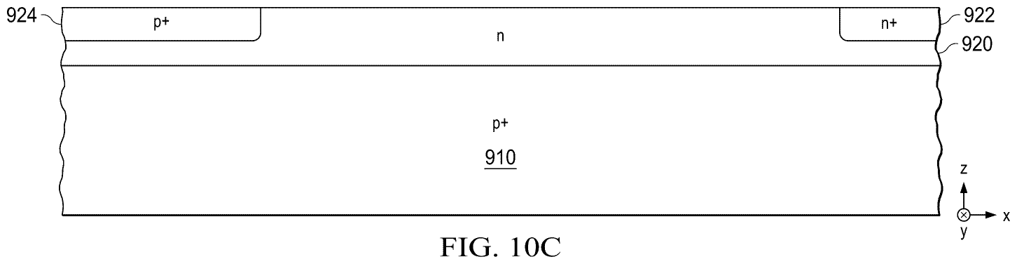

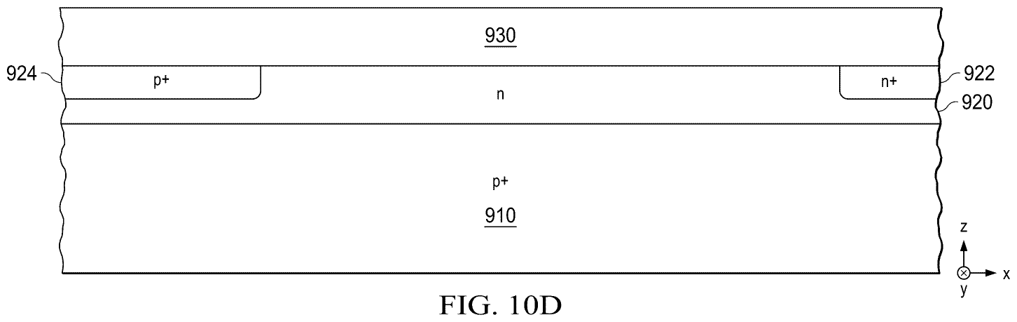

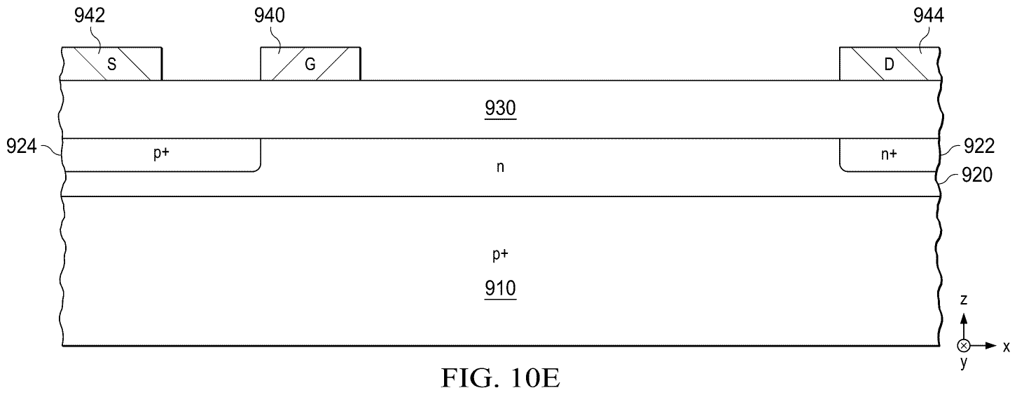

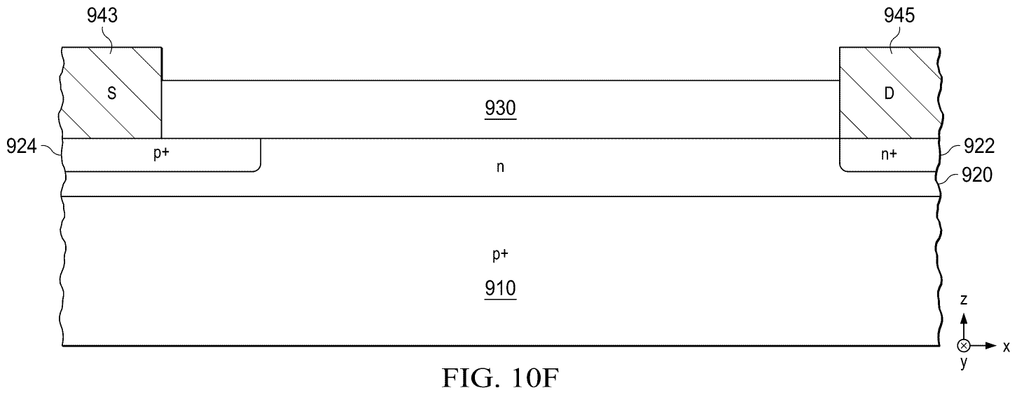

FIGS. 10A-10F illustrate an example of a process of fabricating the semiconductor device 900 of FIGS. 9A and 9B. FIG. 10A shows low-resistivity silicon substrate 910, which may be heavily doped with a p-type dopant, such as B, Al, Ga, In, and the like. As shown in FIG. 10B, n-doped silicon layer 920 may be formed on silicon substrate 910 by, for example, epitaxial growth using, for example, MOCVD, VPE, LPE, or MBE. In some examples, the n-type dopant may be incorporated into n-doped silicon layer 920 during the epitaxial growth. In some examples, the n-type dopant may be implanted after the epitaxial growth to form n-doped silicon layer 920. A vertical silicon diode may be formed by the p⁺-doped silicon substrate 910 and n-doped silicon layer 920. The doping densities and doping profiles of silicon substrate 910 and n-doped silicon layer 920, and/or the thickness of n-doped silicon layer 920 can be tuned to achieve the desired avalanche breakdown voltage of the vertical silicon diode. In some examples, n⁺ ion implantation and dopant activation may be performed at a region of n-doped silicon layer 920 to form n⁺-doped region 922 as shown in FIG. 10C. The n-type dopant in n-doped silicon layer 920 and n⁺-doped region 922 may include, for example, P, As, Sb, and the like. As also shown in FIG. 10C, p⁺ ion implantation and dopant activation may be performed at a region of n-doped silicon layer 920 to form p⁺-doped region 924. A lateral silicon diode may be formed by p⁺-doped region 924 and n-doped silicon layer 920. The doping densities and doping profiles of n-doped silicon layer 920 and p⁺-doped region 924 can be tuned to achieve the desired avalanche breakdown voltage of the lateral silicon diode.

FIG. 10D shows that semiconductor layer stack 930 may be formed on n-doped silicon layer 920. Semiconductor layer stack 930 may be formed by, for example, epitaxially growing the channel layer (e.g., a GaN layer) of the HEMT and then epitaxially growing the barrier layer (e.g., an AlGaN layer) of the HEMT on the channel layer. In some examples, one or more buffer layers may be grown on n-doped silicon layer 920 before growing the channel layer. The epitaxial layers of semiconductor layer stack 930 may be grown using, for example, VPE, LPE, MBE, or MOCVD.

As shown in FIG. 10E, gate structure 940, source structure 942, and drain structure 944 of the HEMT may be formed on and/or in semiconductor layer stack 930. As described above, in some examples, gate structure 940 may include a p-doped semiconductor layer (e.g., a p-GaN layer) formed on the barrier layer and a gate electrical contact formed on the p-doped semiconductor layer, such that the HEMT may be an enhancement mode HEMT. In some examples, gate structure 940 may include a gate electrical contact (a metal electrode) formed over the barrier layer, and the HEMT may be a depletion mode HEMT. Source structure 942 and drain structure 944 may be formed on and/or in semiconductor layer stack 930, and may be electrically coupled to the channel layer of the HEMT through physical contact or tunneling effect. As described above, gate structure 940, source structure 942, and drain structure 944 may include, for example, Cu, W, Au, Al, Ti, Ni, Pt, a metal alloy, or a combination thereof.

FIG. 10F shows that at least one source deep contact 943 may be formed to electrically couple source structure 942 to the anode (e.g., p⁺-doped region 924) of the lateral silicon diode. Source deep contact 943 may extent through semiconductor layer stack 930 to form a low-resistance metal-semiconductor contact with p⁺-doped region 924. At least one drain deep contact 945 may be formed to electrically couple drain structure 944 to the cathode (e.g., n-doped silicon layer 920) of the lateral silicon diode through n⁺-doped region 922. For example, drain deep contact 945 may extent through semiconductor layer stack 930 to form a low-resistance metal-semiconductor contact with n⁺-doped region 922 in n-doped silicon layer 920. Source deep contact 943 and drain deep contact 945 may be formed using the same fabrication processes, such as semiconductor etching and metal deposition.

In the examples shown in FIGS. 3A-10F, the base silicon substrates for forming the silicon diodes may be p-doped either lightly or heavily. In some examples, the base silicon substrates for forming the silicon diodes may be n-doped either lightly or heavily. P-type silicon substrates may be more popular and more widely adopted due to the lower cost and wafer slip resistance, compared with n-type silicon substrates. In some examples, the avalanche diode may be formed in the semiconductor layer stack that includes the non-silicon channel layer and the barrier layer, rather than in the silicon substrate.

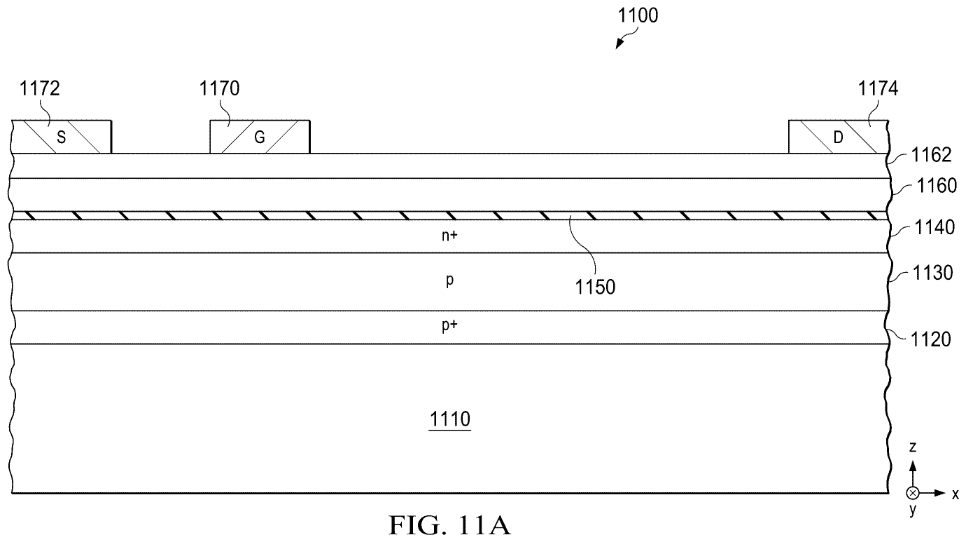

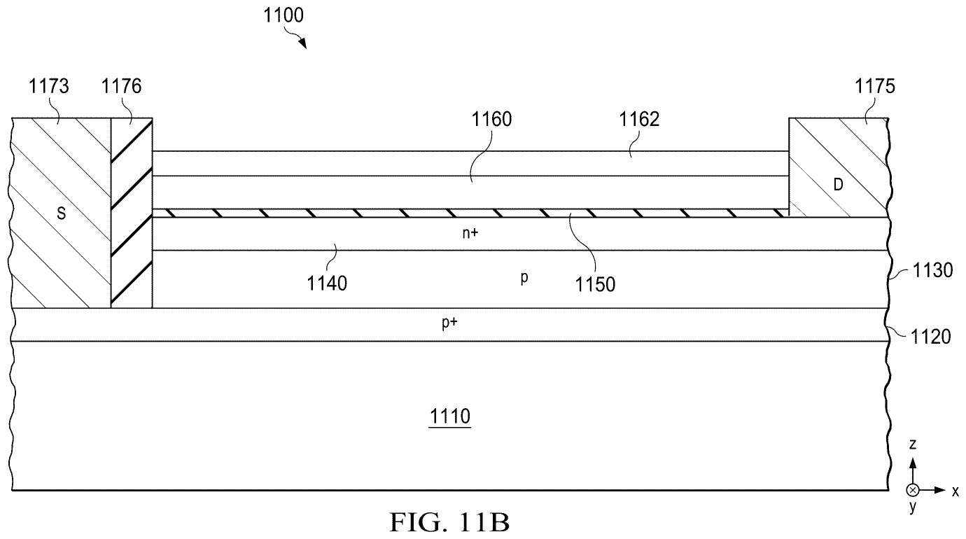

FIGS. 11A and 11B are cross-sectional views of an example of a semiconductor device 1100 including an HEMT and a diode on a same semiconductor die. In the illustrated example, semiconductor device 1100 includes a substrate 1110, which may include, for example, a silicon substrate, a silicon carbide substrate, an SOI substrate, a sapphire substrate, a GaN substrate, a GaAs substrate, an engineered GaN substrate (e.g., a QST substrate), a substrate including another semiconductor material that has a bandgap wider than the bandgap of silicon, or any other suitable substrate.

A semiconductor layer stack may be formed on substrate 1110 by, for example, epitaxial growth techniques such as MOCVD, VPE, LPE, or MBE. In the example illustrated in FIGS. 11A and 11B, the semiconductor layer stack may include a p⁺-doped GaN layer 1120, a p-doped GaN layer 1130, an n⁺-doped GaN layer 1140, a conductive shield structure 1150, a channel layer 1160, and a barrier layer 1162. A vertical GaN-based diode may be formed by p-doped GaN layer 1130 and n⁺-doped GaN layer 1140. The p-type dopant for doping the GaN layers may include, for example, Mg, Ca, Zn, or Be. The n-type dopant for doping the GaN layers may include, for example, Si or Ge. The dopants may be incorporated into the GaN layers and activated during the epitaxial growth, and thus no ion implantation may be needed to form the doped GaN layers. The doping densities, doping profiles, and thicknesses of p-doped GaN layer 1130 and n⁺-doped GaN layer 1140 can be selected to achieve the desired avalanche breakdown voltage of the vertical GaN-based diode. Moreover, the example shown in FIG. 11A and 11B allows all GaN integration of GaN HEMT and a vertical GaN diode, which can simplify the fabrication process. For example, diode creation does not need additional doping of substrate 1110.

Conductive shield structure 1150 can include, for example, a p-GaN layer or another voltage sustaining insulator. For example, conductive shield structure 1150 may be heavily doped with carbon to become semi-insulating or p-doped with deep acceptor levels (e.g., Ev+0.9 eV). Another example of conductive shield structure 1150 can be a conductive layer populated with charge. Examples of a conductive shield structure, or a conductive back barrier, are described in U.S. patent application Ser. No. 18/326,698, titled “INTEGRATED DEVICES WITH CONDUCTIVE BARRIER STRUCTURE,” filed on May 31, 2023, and U.S. patent application Ser. No. 18/534,056, titled “INTEGRATED DEVICES WITH CONDUCTIVE BARRIER STRUCTURE,” filed on Dec. 8, 2023, the entireties of which are herein incorporated by reference. In some examples, conductive shield structure 1150 includes, e.g., as a confinement layer, an aluminum gallium nitride (AlGaN) layer, an aluminum nitride (AlN) layer, an aluminum antimony nitride (AlSbN) layer, or an aluminum indium nitride (AlInN) layer, and includes, e.g., as a low bandgap energy material layer, a gallium nitride (GaN) layer. In examples in which conductive barrier isolation layer 1150 includes a gallium nitride (GaN) layer, conductive shield structure 1150 may be referred to as a conductive GaN barrier structure. Other materials may be implemented for one or more layers of the conductive barrier structure. In some examples, the material of conductive shield structure 1150 is or includes intrinsic (e.g., undoped) material. In some examples, material(s) of conductive shield structure 1150 includes a doped material. In some examples, a confinement layer and a low bandgap energy material layer may be doped with carbon, magnesium, or the like. In some examples, a confinement layer may be doped with magnesium, and a low bandgap energy material layer may be doped with carbon. Other dopants may be implemented in the conductive shield structure 1150. A confinement layer may be doped with a uniform dopant concentration or may be doped with a lateral dopant gradient concentration (e.g., having a concentration gradient along the x or y axis), to introduce IR drop and charge depletion.

Channel layer 1160 may include, for example, an undoped GaN layer. Barrier layer 1162 may include, for example, an AlGaN layer. In some examples, one or more buffer layers may be grown on substrate 1110, before growing the semiconductor layer stack. Conductive shield structure 1150 can shield channel layer 1160 from the high voltage in p-doped GaN layer 1130 and n⁺-doped GaN layer 1140, which form the vertical diode as described above, in the avalanche event to mitigate backgating effect on the HEMT.

A gate structure 1170, a source structure 1172, and a drain structure 1174 may then be formed on or in the semiconductor layer stack to form the HEMT that includes channel layer 1160 and barrier layer 1162. In some examples, gate structure 1170 may include a gate electrical contact (a metal electrode) over barrier layer 1162, and the HEMT may be a depletion mode high electron mobility transistor. In some examples, gate structure 1170 may include a p-doped semiconductor layer (e.g., a p-GaN layer) formed on barrier layer 1162 and a gate electrical contact formed on the p-doped semiconductor layer, and the HEMT may be an enhancement mode high electron mobility transistor.

Source structure 1172 may be formed on and/or in the semiconductor layer stack, and may be electrically coupled to channel layer 1160 of the HEMT through physical contact or tunneling effect. Source structure 1172 may include or may be electrically coupled to at least one source deep contact 1173 formed at one or more regions of semiconductor device 1100 and extending through barrier layer 1162, channel layer 1160, conductive shield structure 1150, n⁺-doped GaN layer 1140, and p-doped GaN layer 1130 to contact p⁺-doped GaN layer 1120. Thus, source structure 1172 may be electrically coupled to p⁺-doped GaN layer 1120 through at least one source deep contact 1173. Source deep contact 1173 may be surrounded by an isolation layer 1176 to isolate source deep contact 1173 from at least n⁺-doped GaN layer 1140. Isolation layer 1176 may include a dielectric material such as silicon dioxide, silicon nitride, aluminum oxide, and the like.

Drain structure 1174 may also be formed on and/or in the semiconductor layer stack, and may be electrically coupled to channel layer 1160 of the HEMT through physical contact or through tunneling effect. Drain structure 1174 may include or may be electrically coupled to at least one drain deep contact 1175 formed at one or more regions of semiconductor device 1100 and extending through barrier layer 1162, channel layer 1160, and conductive shield structure 1150 to contact n⁺-doped GaN layer 1140.

The gate electrical contact of gate structure 1170, source structure 1172, source deep contact 1173, drain structure 1174, and drain deep contact 1175 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 1170, source structure 1172, source deep contact 1173, drain structure 1174, and drain deep contact 1175.

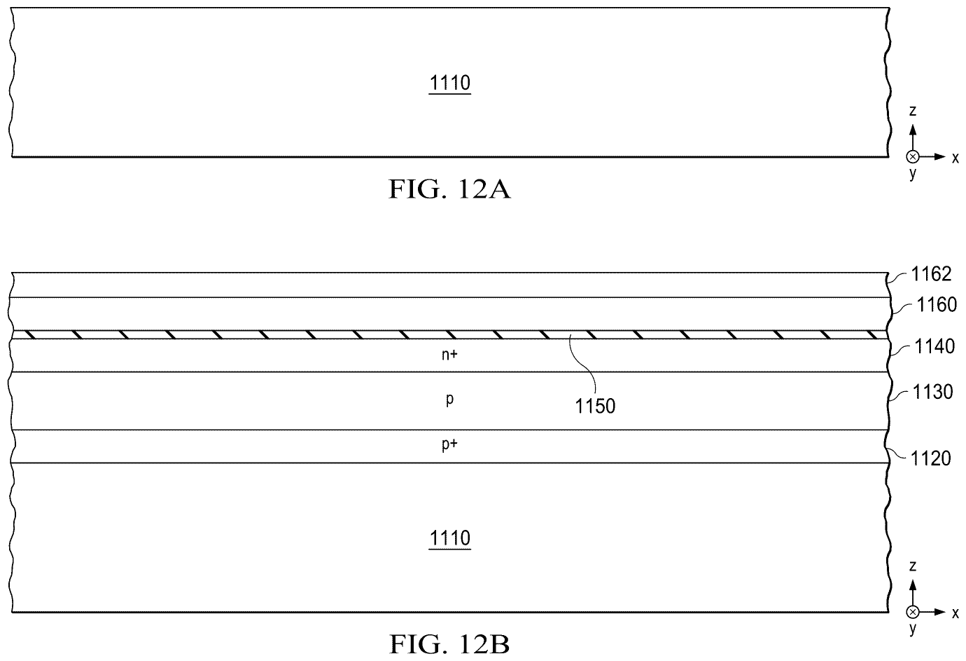

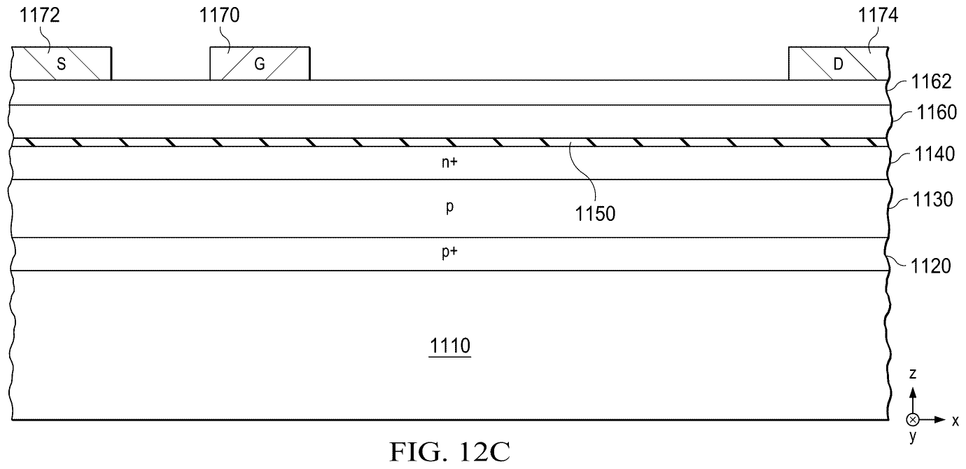

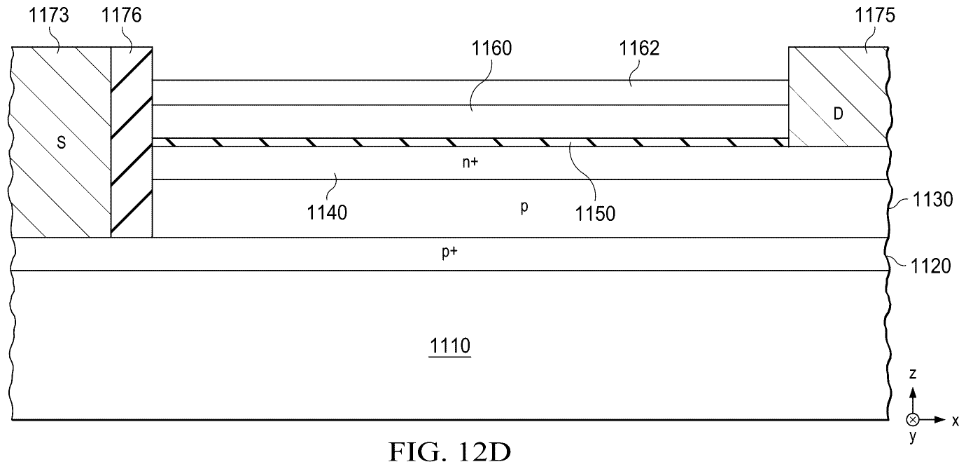

FIGS. 12A-12D illustrate an example of a process of fabricating semiconductor device 1100 of FIGS. 11A and 11B. FIG. 12A shows a substrate 1110, which may include, for example, a silicon substrate, a silicon carbide substrate, an SOI substrate, a sapphire substrate, a GaN substrate, a GaAs substrate, an engineered GaN substrate (e.g., a QST substrate), a substrate including another semiconductor material that has a bandgap wider than a bandgap of silicon, or any other suitable substrate. In one example, substrate 1110 may be a silicon substrate. Substrate 1110 may be doped or undoped.

FIG. 12B shows a semiconductor layer stack epitaxially grown on substrate 1110. The semiconductor layer stack may be grown using, for example, MOCVD, VPE, LPE, or MBE techniques, and may include, for example, p⁺-doped GaN layer 1120, p-doped GaN layer 1130, n⁺-doped GaN layer 1140, channel layer 1160, and barrier layer 1162. In some examples, the semiconductor layer stack may also include conductive shield structure 1150 between n⁺-doped GaN layer 1140 and channel layer 1160. A vertical GaN-based diode may be formed by p-doped GaN layer 1130 and n⁺-doped GaN layer 1140. The p-type dopant for doping the GaN layers may include, for example, Mg, Ca, Zn, or Be. The n-type dopant for doping the GaN layers may include, for example, Si or Ge. The dopants may be incorporated into the GaN layers and activated during the epitaxial growth, and thus no ion implantation may be needed to form the doped GaN layers. The doping densities, doping profiles, and/or thicknesses of p-doped GaN layer 1130 and n⁺-doped GaN layer 1140 can be tuned to achieve the desired avalanche breakdown voltage of the vertical GaN-based diode. Channel layer 1160 may include, for example, an undoped GaN layer. Barrier layer 1162 may include, for example, an AlGaN layer. In some examples, one or more buffer layers may be grown on substrate 1110, before growing the semiconductor layer stack.

As shown in FIG. 12C, gate structure 1170, source structure 1172, and drain structure 1174 of the HEMT may be formed on and/or in the semiconductor layer stack. As described above, in some examples, gate structure 1170 may include a p-doped semiconductor layer (e.g., a p-GaN layer) formed on barrier layer 1162 and a gate electrical contact formed on the p-doped semiconductor layer, such that the HEMT may be an enhancement mode HEMT. In some examples, gate structure 1170 may include a gate electrical contact (a metal electrode) formed over barrier layer 1162, and the HEMT may be a depletion mode HEMT. Source structure 1172 and drain structure 1174 may be formed on and/or in the semiconductor layer stack, and may be electrically coupled to channel layer 1160 of the HEMT through physical contact or tunneling effect. As described above, gate structure 1170, source structure 1172, and drain structure 1174 may include, for example, Cu, W, Au, Al, Ti, Ni, Pt, a metal alloy, or a combination thereof.

FIG. 12D shows that at least one drain deep contact 1175 may be formed to electrically couple drain structure 1174 to the cathode (e.g., n⁺-doped GaN layer 1140) of the vertical GaN-based diode. Drain deep contact 1175 may extent through barrier layer 1162 and channel layer 1160 to form a low-resistance metal-semiconductor contact with n⁺-doped GaN layer 1140. At least one source deep contact 1173 may be formed to electrically couple source structure 1172 to the anode (e.g., p-doped GaN layer 1130) of the vertical GaN-based diode through p⁺-doped GaN layer 1120. Source deep contact 1173 may extent through barrier layer 1162, channel layer 1160, n⁺-doped GaN layer 1140, and p-doped GaN layer 1130 to form a low-resistance metal-semiconductor contact with p⁺-doped GaN layer 1120. Isolation layer 1176 may be formed in the semiconductor layer stack to electrically isolate source deep contact 1173 from at least n⁺-doped GaN layer 1140. In one example, the semiconductor layer stack may be etched at the source region to form one or more trenches, a dielectric material may be deposited to fill the one or more trenches, the dielectric material in the center region of each trench may be removed to form a hole surrounded by isolation layer 1176, and a metal material may be deposited into the hole to form a source deep contact 1173 that is surrounded by isolation layer 1176.

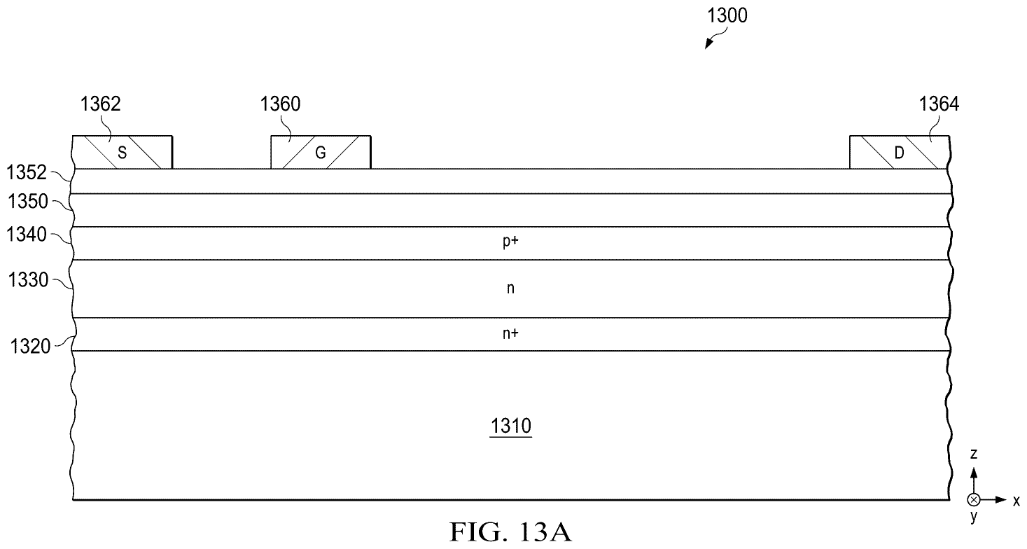

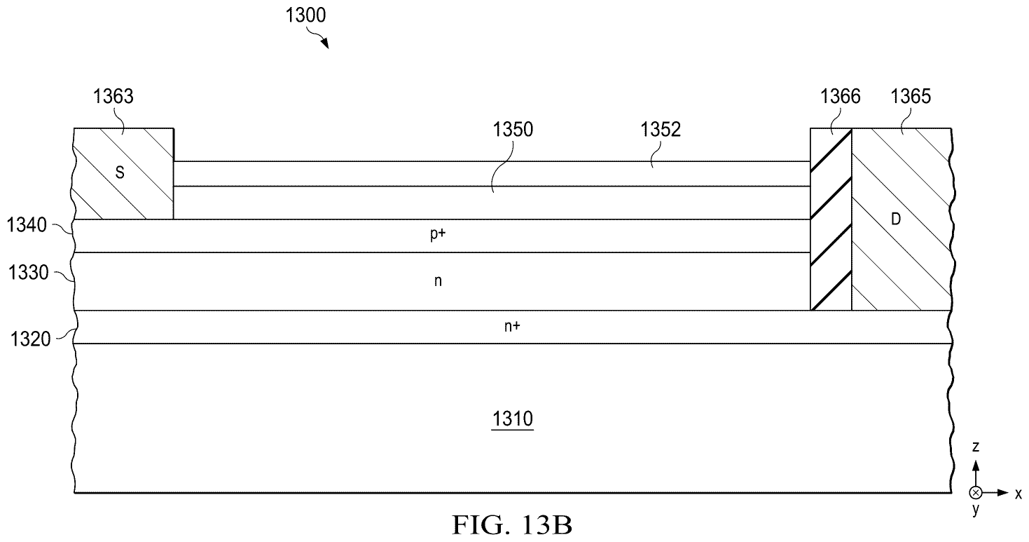

FIGS. 13A and 13B are cross-sectional views of an example of a semiconductor device 1300 including an HEMT and a diode on a same semiconductor die. In the illustrated example, semiconductor device 1300 includes a substrate 1310, which may include, for example, a silicon substrate, a silicon carbide substrate, an SOI substrate, a sapphire substrate, a GaN substrate, a GaAs substrate, an engineered GaN substrate (e.g., a QST substrate), a substrate including another semiconductor material that has a bandgap wider than a bandgap of silicon, or any other suitable substrate. Substrate 1310 can be doped or undoped.

A semiconductor layer stack may be formed on substrate 1310 by, for example, epitaxial growth processes such as MOCVD, VPE, LPE, or MBE. In the example illustrated in FIGS. 13A and 13B, the semiconductor layer stack may include an n⁺-doped GaN layer 1320, an n-doped GaN layer 1330, a p⁺-doped GaN layer 1340, a channel layer 1350, and a barrier layer 1352. A vertical GaN-based diode may be formed by p⁺-doped GaN layer 1340 and n-doped GaN layer 1330. The p-type dopant for doping the GaN layers may include, for example, Mg, Ca, Zn, or Be. The n-type dopant for doping the GaN layers may include, for example, Si or Ge. The dopants may be incorporated into the GaN layers and activated during the epitaxial growth, and thus no ion implantation may be needed to form the doped GaN layers. The doping densities, doping profiles, and/or thicknesses of p⁺-doped GaN layer 1340 and n-doped GaN layer 1330 can be selected to achieve the desired avalanche breakdown voltage of the vertical GaN-based diode. Channel layer 1350 may include, for example, an undoped GaN layer. Barrier layer 1352 may include, for example, an AlGaN layer. In some examples, one or more buffer layers may be grown on substrate 1310, before growing the semiconductor layer stack.

In the example shown in FIGS. 13A and 13B, the doping process in the formation of n⁺-doped GaN layer 1320 on substrate 1310 can be easier and more effective than the doping process in the formation of p⁺-doped GaN layer 1120 on substrate 1110 due to material properties, such as the lower activation energy of the n-type dopants compared with p-type dopants. Also, in FIGS. 13A and 13B, conductive shield structure 1150 of FIGS. 11A and 11B can be omitted because, at a high drain bias, the n-p⁺ junction formed by n-doped GaN layer 1330 and p⁺-doped GaN layer 1340 is reverse biased and thus would block the voltage. Most of the high voltage may be dropped across the reverse biased n-p⁺ junction, rather than across a GaN buffer layer, and thus the backgating effect on the HEMT may be reduced.

A gate structure 1360, a source structure 1362, and a drain structure 1364 may then be formed on or in the semiconductor layer stack to form the HEMT that includes channel layer 1350 and barrier layer 1352. In some examples, gate structure 1360 may include a gate electrical contact (a metal electrode) over barrier layer 1352, and the HEMT may be a depletion mode high electron mobility transistor. In some examples, gate structure 1360 may include a p-doped semiconductor layer (e.g., a p-GaN layer) formed on barrier layer 1352 and a gate electrical contact formed on the p-doped semiconductor layer, and the HEMT may be an enhancement mode high electron mobility transistor.

Source structure 1362 may be formed on and/or in the semiconductor layer stack, and may be electrically coupled to channel layer 1350 of the HEMT through physical contact or tunneling effect. Source structure 1362 may include or may be electrically coupled to at least one source deep contact 1363 formed at one or more regions of semiconductor device 1300 and extending through barrier layer 1352 and channel layer 1350 to contact p⁺-doped GaN layer 1340. Thus, source structure 1362 may be electrically coupled to p⁺-doped GaN layer 1340 through at least one source deep contact 1363.

Drain structure 1364 may also be formed on and/or in the semiconductor layer stack, and may be electrically coupled to channel layer 1350 of the HEMT through physical contact or through tunneling effect. Drain structure 1364 may include or may be electrically coupled to at least one drain deep contact 1365 formed at one or more regions of semiconductor device 1300 and extending through barrier layer 1352, channel layer 1350, p⁺-doped GaN layer 1340, and n-doped GaN layer 1330 to contact n⁺-doped GaN layer 1320. Drain deep contact 1365 may be surrounded by an isolation layer 1366 to isolate drain deep contact 1365 from at least p⁺-doped GaN layer 1340. Isolation layer 1366 may include a dielectric material such as silicon dioxide, silicon nitride, aluminum oxide, and the like.

The gate electrical contact of gate structure 1360, source structure 1362, source deep contact 1363, drain structure 1364, and drain deep contact 1365 may include, for example, Cu, W, Au, Al, Ti, Ni, Pt, a metal alloy, or a combination thereof. In some examples, one or more metal barrier layers and/or one or more adhesion layers (e.g., TiN, TaN, and the like, or a combination thereof) may be formed between the dielectric and/or semiconductor materials and the metal materials of the gate electrical contact of gate structure 1360, source structure 1362, source deep contact 1363, drain structure 1364, and drain deep contact 1365.

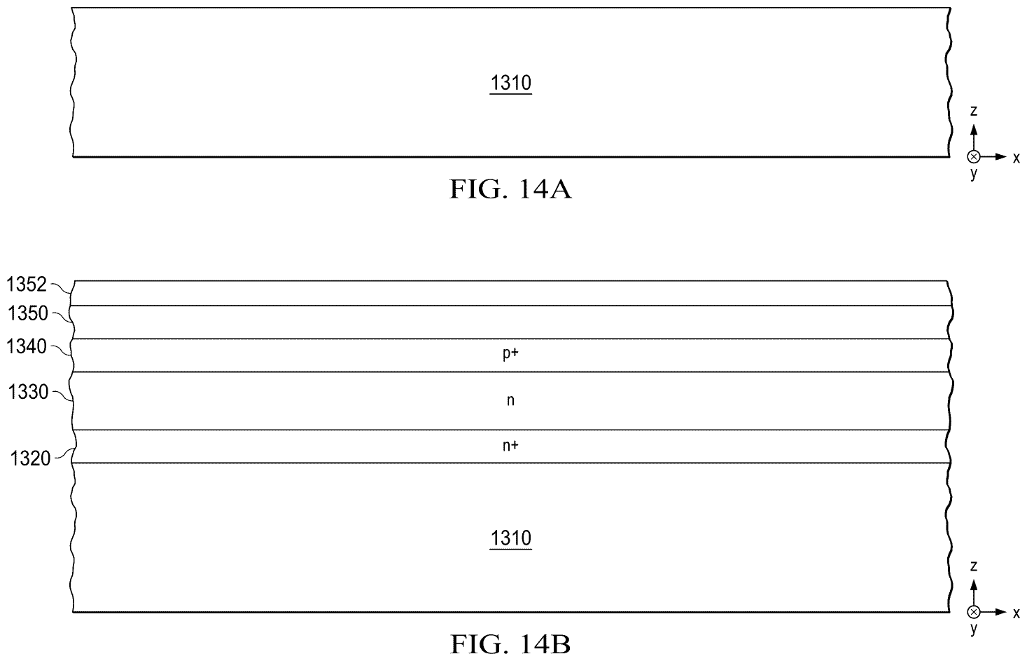

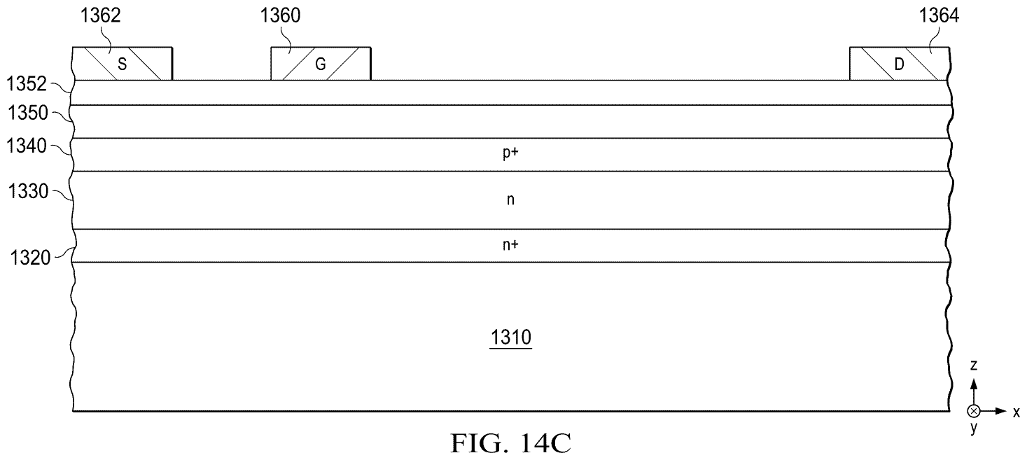

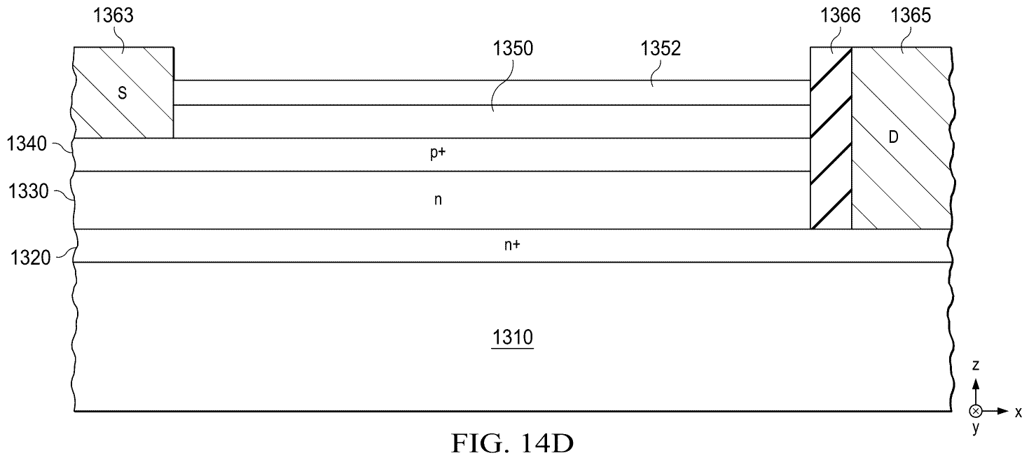

FIGS. 14A-14D illustrate an example of a process of fabricating semiconductor device 1300 of FIGS. 13A and 13B. FIG. 14A shows a substrate 1310, which may include, for example, a silicon substrate, a silicon carbide substrate, an SOI substrate, a sapphire substrate, a GaN substrate, a GaAs substrate, an engineered GaN substrate (e.g., a QST substrate), a substrate including another semiconductor material that has a bandgap wider than a bandgap of silicon, or any other suitable substrate. In one example, substrate 1310 may be a silicon substrate. Substrate 1310 may be doped or undoped.

FIG. 14B shows a semiconductor layer stack epitaxially grown on substrate 1310. The semiconductor layer stack may be grown using, for example, MOCVD, VPE, LPE, or MBE techniques, and may include, for example, n⁺-doped GaN layer 1320, n-doped GaN layer 1330, p⁺-doped GaN layer 1340, channel layer 1350, and barrier layer 1352. In some examples, the semiconductor layer stack may also include an electrical isolation layer between p⁺-doped GaN layer 1340 and channel layer 1350. A vertical GaN-based diode may be formed by p⁺-doped GaN layer 1340 and n-doped GaN layer 1330. The p-type dopant for doping the GaN layers may include, for example, Mg, Ca, Zn, or Be. The n-type dopant for doping the GaN layers may include, for example, Si or Ge. The dopants may be incorporated into the GaN layers and activated during the epitaxial growth, and thus no ion implantation may be needed to form the doped GaN layers. The doping densities, doping profiles, and/or thicknesses of n-doped GaN layer 1330 and p⁺-doped GaN layer 1340 can be tuned to achieve the desired avalanche breakdown voltage of the vertical GaN-based diode. Channel layer 1350 may include, for example, an undoped GaN layer. Barrier layer 1352 may include, for example, an AlGaN layer. In some examples, one or more buffer layers may be grown on substrate 1310, before growing the semiconductor layer stack.

As shown in FIG. 14C, gate structure 1360, source structure 1362, and drain structure 1364 of the HEMT may be formed on and/or in the semiconductor layer stack. As described above, in some examples, gate structure 1360 may include a p-doped semiconductor layer (e.g., a p-GaN layer) formed on barrier layer 1352 and a gate electrical contact formed on the p-doped semiconductor layer, such that the HEMT may be an enhancement mode HEMT. In some examples, gate structure 1360 may include a gate electrical contact (a metal electrode) formed over barrier layer 1352, and the HEMT may be a depletion mode HEMT. Source structure 1362 and drain structure 1364 may be formed on and/or in the semiconductor layer stack, and may be electrically coupled to channel layer 1350 of the HEMT through physical contact or tunneling effect. As described above, gate structure 1360, source structure 1362, and drain structure 1364 may include, for example, Cu, W, Au, Al, Ti, Ni, Pt, a metal alloy, or a combination thereof.

FIG. 14D shows that at least one source deep contact 1363 may be formed to electrically couple source structure 1362 to the anode (e.g., p⁺-doped GaN layer 1340) of the vertical GaN-based diode. Source deep contact 1363 may extent through barrier layer 1352 and channel layer 1350 to form a low-resistance metal-semiconductor contact with p⁺-doped GaN layer 1340. At least one drain deep contact 1365 may be formed to electrically couple drain structure 1364 to the cathode (e.g., n-doped GaN layer 1330) of the vertical GaN-based diode through n⁺-doped GaN layer 1320. Drain deep contact 1365 may extent through barrier layer 1352, channel layer 1350, p⁺-doped GaN layer 1340, and n-doped GaN layer 1330 to form a low-resistance metal-semiconductor contact with n⁺-doped GaN layer 1320. Isolation layer 1366 may be formed in the semiconductor layer stack to electrically isolate drain deep contact 1365 from at least p⁺-doped GaN layer 1340. In one example, the semiconductor layer stack may be etched at the drain region to form one or more trenches, a dielectric material may be deposited to fill the one or more trenches, the dielectric material in the center region of each trench may be removed to form a hole surrounded by isolation layer 1366, and a metal material may be deposited into the hole to form a drain deep contact 1365 that is surrounded by isolation layer 1366.

Even though the examples described above include silicon or GaN-based p-n junction diodes monolithically integrated with HEMTs, other avalanche diodes may also be monolithically integrated with HEMTs to provide the avalanche capabilities. For example, the avalanche diode can be a silicon Schottky diode, a GaN-based Schottky diode, a SiC-based p-n junction diode, a SiC Schottky diode, or another diode formed using another semiconductor material and/or a metal material.

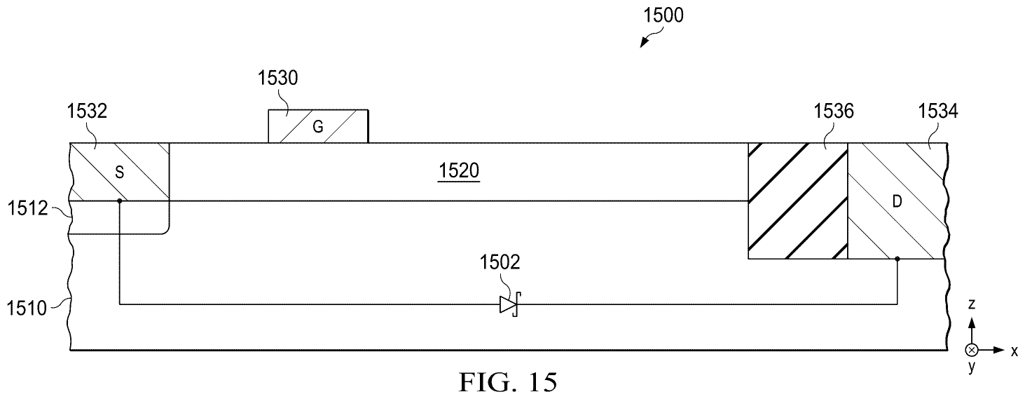

FIG. 15 is a cross-sectional view of an example of a semiconductor device 1500 including an HEMT and a diode on a same semiconductor die. In the illustrated example, semiconductor device 1500 includes a substrate 1510 that may include silicon, GaN, SiC, or another semiconductor material. Substrate 1510 may be lightly doped with a p-type dopant. A p⁺-doped region 1512 may be formed at a region of substrate 1510 by, for example, p-type ion implantation and dopant activation. A semiconductor layer stack 1520 may be formed on substrate 1510 by, for example, epitaxial growth. Semiconductor layer stack 1520 may include at least a channel layer and a barrier layer that may form a heterostructure with a 2DEG channel at the interface of the heterostructure. For example, the channel layer may include GaN, and the barrier layer may include AlGaN. A gate structure 1530, a source structure 1532, and a drain structure 1534 may then be formed on or in semiconductor layer stack 1520 to form the HEMT that includes the channel layer and the barrier layer. The gate electrical contact of gate structure 1530, source structure 1532, and drain structure 1534 may include, for example, Cu, W, Au, Al, Ti, Ni, Pt, a metal alloy, or a combination thereof.

In some examples, gate structure 1530 may include a gate electrical contact (a metal electrode) over the barrier layer, and the HEMT may be a depletion mode high electron mobility transistor. In some examples, gate structure 1530 may include a p-doped semiconductor layer (e.g., a p-GaN layer) formed on the barrier layer and a gate electrical contact formed on the p-doped semiconductor layer, and the HEMT may be an enhancement mode high electron mobility transistor.

Source structure 1532 may be formed on and/or in semiconductor layer stack 1520, and may be electrically coupled to the channel layer of the HEMT through physical contact or tunneling effect. Source structure 1532 may include or may be electrically coupled to at least one source deep contact formed at one or more regions of semiconductor device 1500 and extending through semiconductor layer stack 1520 to form a low-resistance contact with p⁺-doped region 1512. Thus, source structure 1532 may be electrically coupled to p-doped substrate 1510 through at least one source deep contact and p⁺-doped region 1512, such that the resistance between source structure 1532 and substrate 1510 may be small.

Drain structure 1534 may also be formed on and/or in semiconductor layer stack 1520, and may be electrically coupled to the channel layer of the HEMT through physical contact or through tunneling effect. Drain structure 1534 may include or may be electrically coupled to at least one drain deep contact formed at one or more regions of semiconductor device 1500 and extending through semiconductor layer stack 1520 to contact p-doped substrate 1510. The drain deep contact and the p-doped substrate 1510 may form a Schottky diode 1502. The drain deep contact may be isolated from semiconductor layer stack 1520 by an isolation layer 1536, which may include, for example, a dielectric material such as silicon dioxide, silicon nitride, aluminum oxide, and the like.

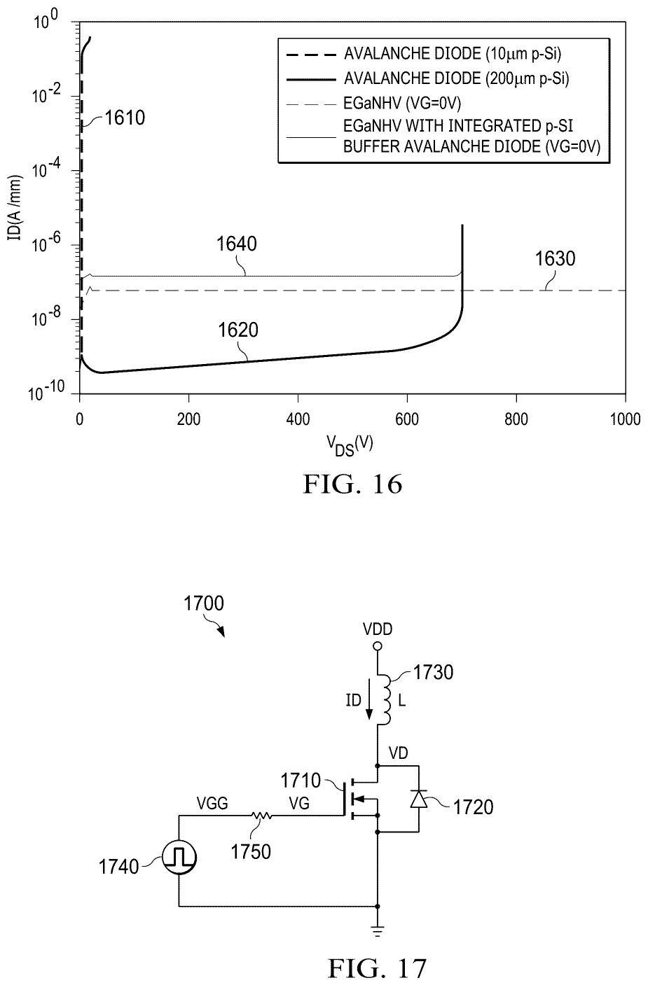

FIG. 16 includes a graph illustrating simulation results of the breakdown of different GaN-based transistors. A curve 1610 in FIG. 16 is a current-voltage (I-V) curve of a silicon avalanche diode including a p-doped silicon layer having a thickness about 10 μm. Because of the thin p-doped silicon layer, the silicon avalanche diode may have a low avalanche breakdown voltage. The avalanche breakdown voltage of the silicon avalanche diode may be changed by, for example, changing the doping density (and thus the length of the depletion region) and/or the thickness of the lightly doped semiconductor layer. For example, when the thickness of the p-doped silicon layer of the silicon avalanche diode is about 200 μm, the avalanche breakdown voltage of the silicon avalanche diode may be increased to between about 600-700 V, as shown by an I-V curve 1620.

FIG. 16 also show an I-V curve 1630 of a GaN HEMT without an integrated avalanche diode, when the GaN HEMT is turned off. The GaN HEMT may have a high breakdown voltage. As shown by an I-V curve 1640, when a silicon avalanche diode having a p-doped silicon layer with a thickness about 200 μm is integrated with the GaN HEMT, the breakdown voltage of the integrated device may be similar to the avalanche breakdown voltage of the standalone silicon avalanche diode shown by I-V curve 1620, such as between about 600-700 V. Thus, the avalanche diode can provide avalanche breakdown capability to the integrated device.

FIG. 17 includes a schematic 1700 illustrating an example of an operation of an GaN-based transistor 1710 including an integrated diode 1720 under unclamped inductive switching condition. Schematic 1700 shows a signal source 1740 driving the gate of GaN-based transistor 1710 through a resistor 1750. The drain of GaN-based transistor 1710 may be coupled to a voltage supply through an inductor 1730. The source of GaN-based transistor 1710 may be connected to ground. The anode of diode 1720 may be coupled to the source of GaN-based transistor 1710, while the cathode of diode 1720 may be coupled to the drain of GaN-based transistor 1710. The supply voltage of the voltage supply is labeled as VDD. The current between the drain terminal and the source terminal of GaN-based transistor 1710 (including the current flowing through GaN-based transistor 1710 and the current flowing through diode 1720) is labeled as ID. The voltage level at the drain of GaN-based transistor 1710 is labeled as VD. The voltage level at the gate of GaN-based transistor 1710 is labeled as VG.

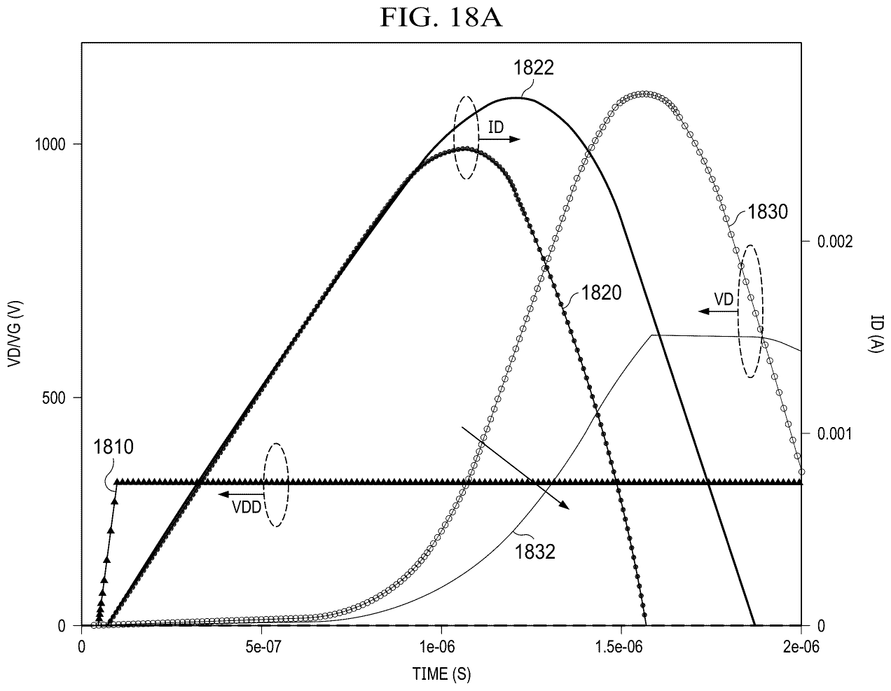

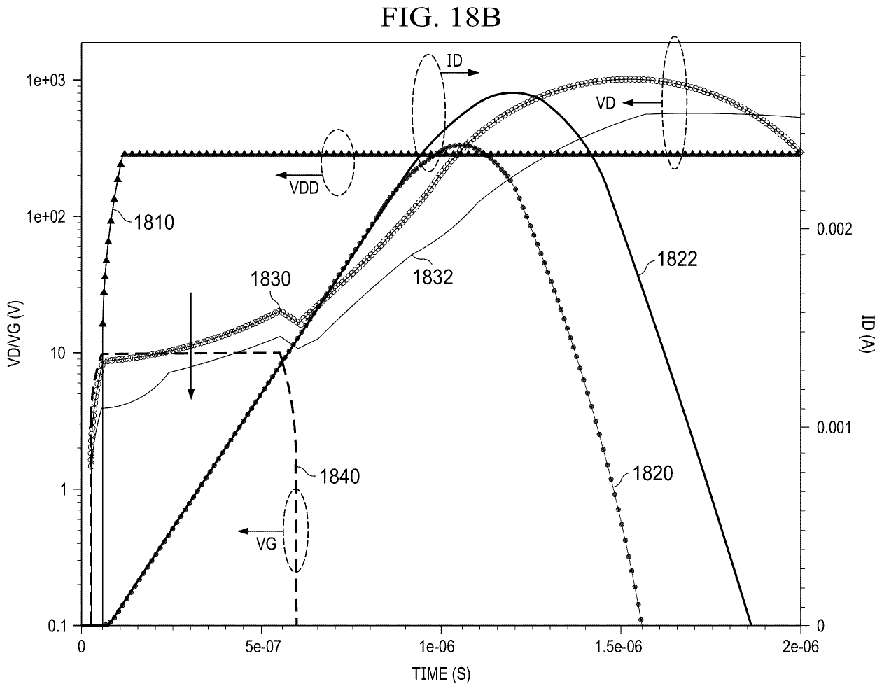

FIGS. 18A and 18B illustrate simulation results of the circuit shown by schematic 1700 of FIG. 17 during a switching operation. FIG. 18A shows the simulated VD and VG in the linear scale, whereas FIG. 18B shows the simulated VD and VG in the logarithmic scale. In the illustrated example, GaN-based transistor 1710 may be switched off from an on state, and the supply voltage VDD of the voltage supply may be about 300 V as shown by a curve 1810. A curve 1840 shows the switching of voltage level VG from about 10 V to 0 V to turn off GaN-based transistor 1710. A curve 1820 shows the change of current ID during the switching when the circuit does not include diode 1720, while a curve 1822 shows the change of current ID during the switching when the circuit includes diode 1720.

A curve 1830 shows the change of voltage level VD during the switching when the circuit does not include diode 1720, while a curve 1832 shows the change of voltage level VD during the switching when the circuit includes diode 1720. Curves 1830 and 1832 show that, with diode 1720, the change of the voltage level VD (dVD/dt) may be slower, and the voltage level VD may be clamped at the breakdown voltage of diode 1720 (e.g., between about 600-700 V). Curves 1820 and 1822 and curves 1830 and 1832 in the logarithmic scale also show that, with diode 1720, VD may be lower at any given time during the switching and thus the channel resistance R_{DSON} of GaN-based transistor 1710 may be lower.

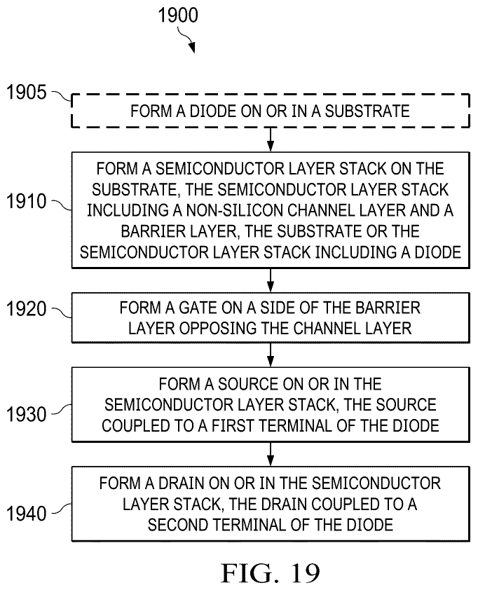

FIG. 19 includes a flowchart 1900 illustrating an example of a process of fabricating a semiconductor device including an HEMT and a diode on a same semiconductor die. It is noted that the operations illustrated in FIG. 19 provide particular processes for fabricating some examples of semiconductor devices with integrated avalanche diodes disclosed herein according to certain examples. Other sequences of operations can also be performed to fabricate the semiconductor devices according to alternative examples. For example, alternative examples may perform the operations in a different order. Moreover, the individual operations illustrated in FIG. 19 can include multiple sub-operations that can be performed in various sequences as appropriate for the individual operation. Furthermore, some operations can be added or removed depending on the particular example. In some examples, two or more operations may be performed in parallel. One of ordinary skill in the art would recognize many variations, modifications, and alternatives.

Optional operations at block 1905 of flowchart 1900 may include forming a diode on or in a substrate. In some examples, the substrate may include a semiconductor substrate, such as a silicon, GaN, engineered GaN, or SiC substrate, and the diode may be formed in the substrate by ion implantation into the substrate. In one example as shown in FIGS. 3A-4B, a diode may be formed in the substrate by forming a first doped (e.g., n⁺-type) semiconductor layer in a layer of the substrate, and forming a section doped (e.g., p-type semiconductor layer) over the first doped semiconductor layer to form the diode in the substrate. The first doped semiconductor layer and the second doped semiconductor layer may be formed in the substrate by, for example, ion implantation and dopant activation. In another example, the substrate (or a layer of the substrate) may be p or n doped, and a region of the substrate may be oppositely doped to form the diode with other regions of the substrate, as shown in, for example, FIGS. 5A-6B. In some examples, a region of a lightly doped semiconductor layer of the diode may be heavily doped with the same type of dopant to provide a low-resistance contact with the lightly doped semiconductor layer.

In some examples, the substrate may or may not be a semiconductor substrate, and the diode may be formed on the substrate by growing one or more semiconductor layers on the substrate. For example, the substrate may be p or n doped, and the diode may be formed by forming (e.g., epitaxially growing) an oppositely doped semiconductor layer on the substrate, where the oppositely doped semiconductor layer and the substrate may form the diode, as shown in, for example, FIGS. 7A-8B. In another example, the substrate may be doped or undoped, and the diode may be formed by forming (e.g., epitaxially growing) a doped semiconductor layer on the substrate, and forming an oppositely doped region in the doped semiconductor layer, where the oppositely doped region and the doped semiconductor layer may form the diode, as shown in, for example, FIGS. 9A-10C. In some examples, a region of a lightly doped semiconductor layer of the diode may be heavily doped with the same type of dopant to provide a low-resistance contact with the lightly doped semiconductor layer.

Operations at block 1910 may include forming a semiconductor layer stack on the substrate. The semiconductor layer stack may include at least a non-silicon channel layer and a barrier layer on the channel layer. In some examples, the substrate may include a diode formed thereon or therein as described above with respect to, for example, block 1905. In some examples, the semiconductor layer stack may include a diode formed therein. In one example, the semiconductor layer stack may include a p-type semiconductor layer formed (e.g., epitaxially grown) over the substrate, and an n⁺-type semiconductor layer formed (e.g., epitaxially grown) on the p-type semiconductor layer, where the n⁺-type semiconductor layer and the p-type semiconductor layer may form a vertical diode. In another example, the semiconductor layer stack may include an n-type semiconductor layer formed (e.g., epitaxially grown) over the substrate, and a p⁺-type semiconductor layer formed (e.g., epitaxially grown) on the n-type semiconductor layer, where the p⁺-type semiconductor layer and the n-type semiconductor layer may form a vertical diode.

Operations at block 1920 may include forming a gate on a side of the barrier layer opposing the channel layer. In some examples, the gate may include a gate electrical contact (a metal electrode) over the barrier layer to form a depletion mode high electron mobility transistor. In some examples, the gate may include a p-doped semiconductor layer (e.g., a p-GaN layer) formed on the barrier layer and a gate electrical contact formed on the p-doped semiconductor layer, to form an enhancement mode high electron mobility transistor.

Operations at block 1930 may include forming a source on and/or in the semiconductor layer stack, where the source may be electrically coupled to a first terminal (e.g., the anode) of the diode. The source may be electrically coupled to the channel layer through physical contact or tunneling effect. The source may include or may be electrically coupled to at least one source deep contact formed at one or more regions of the semiconductor device and extending in the semiconductor layer stack to contact the first terminal (e.g., the anode) of the diode, such as a p-doped or p⁺-doped semiconductor layer or semiconductor region. In some examples, an isolation layer may surround the source deep contact to isolate the source deep contact.

Operations at block 1940 may include forming a drain on and/or in the semiconductor layer stack, where the drain may be electrically coupled to a second terminal (e.g., the cathode) of the diode. The drain may be electrically coupled to the channel layer through physical contact or tunneling effect. The drain may include or may be electrically coupled to at least one drain deep contact formed at one or more regions of the semiconductor device and extending in the semiconductor layer stack to contact the second terminal (e.g., the cathode) of the diode, such as an n-doped or n⁺-doped semiconductor layer or semiconductor region. In some examples, an isolation layer may surround the drain deep contact to isolate the drain deep contact.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

1. A semiconductor device comprising:
a substrate;
a semiconductor layer stack on the substrate, the semiconductor layer stack including:
a non-silicon channel layer; and
a barrier layer on the channel layer; and
a gate, a source, and a drain formed on or in the semiconductor layer stack,
wherein at least one of the substrate or the semiconductor layer stack includes a diode, a first terminal of the diode electrically coupled to the source, and a second terminal of the diode electrically coupled to the drain.

2. The semiconductor device of claim 1, wherein:
the substrate includes at least one of silicon, silicon carbide, silicon on insulator (SOI), sapphire, gallium nitride (GaN), engineered GaN, or another semiconductor material having a bandgap wider than a bandgap of silicon; and
the channel layer includes at least one of GaN, AlGaN, or InAlN.

3. The semiconductor device of claim 1, wherein the diode is formed in the substrate.

4. The semiconductor device of claim 3, wherein the substrate includes a p-type semiconductor layer and an n⁺-type semiconductor layer that form the diode in the substrate, wherein the n⁺-type semiconductor layer is on a side of the p-type semiconductor layer opposing the channel layer.

5. The semiconductor device of claim 4, wherein:
the source includes a source contact electrically coupled to a p⁺-type region formed in the p-type semiconductor layer;
the drain includes a drain contact electrically coupled to the n⁺-type semiconductor layer; and
the semiconductor device further comprises an isolation layer laterally between the drain contact and the p-type semiconductor layer and the semiconductor layer stack.

6. The semiconductor device of claim 3, wherein:
the substrate includes a p-type semiconductor layer that includes a p⁺-type region and an n⁺-type region formed therein, the p-type semiconductor layer and the n⁺-type region forming the diode;
the source includes a source contact electrically coupled to the p⁺-type region; and
the drain includes a drain contact electrically coupled to the n⁺-type region.

7. The semiconductor device of claim 3, wherein the substrate includes an n-type semiconductor layer and a p-type semiconductor layer, the p-type semiconductor layer on a side of the n-type semiconductor layer opposing the channel layer.

8. The semiconductor device of claim 7, wherein the n-type semiconductor layer is an epitaxial layer grown on the p-type semiconductor layer.

9. The semiconductor device of claim 7, wherein the n-type semiconductor layer has a lower doping density than the p-type semiconductor layer.

10. The semiconductor device of claim 7, wherein:
the source includes a source contact electrically coupled to the p-type semiconductor layer;
the drain includes a drain contact electrically coupled to an n⁺-type region formed in the n-type semiconductor layer; and
the semiconductor device further comprises an isolation layer laterally between the source contact and the n-type semiconductor layer and the semiconductor layer stack.

11. The semiconductor device of claim 7, wherein:
the n-type semiconductor layer includes a p⁺-type region and an n⁺-type region formed therein;
the source includes a source contact electrically coupled to the p⁺-type region; and
the drain includes a drain contact electrically coupled to the n⁺-type region.

12. The semiconductor device of claim 1, wherein:
the semiconductor layer stack includes a p-type semiconductor layer and an n⁺-type semiconductor layer, the n⁺-type semiconductor layer and the p-type semiconductor layer forming the diode.

13. The semiconductor device of claim 12, wherein the semiconductor layer stack further includes a conductive shield structurer between the channel layer and the n⁺-type semiconductor layer.

14. The semiconductor device of claim 12, wherein:
the source includes a source contact electrically coupled to the p-type semiconductor layer;
the drain includes a drain contact electrically coupled to the n⁺-type semiconductor layer; and
the semiconductor device further comprises an isolation layer laterally between the source contact and the n⁺-type semiconductor layer.

15. The semiconductor device of claim 1, wherein:
the semiconductor layer stack includes an n-type semiconductor layer and a p⁺-type semiconductor layer, the p⁺-type semiconductor layer and the n-type semiconductor layer forming the diode.

16. The semiconductor device of claim 15, wherein:
the source includes a source contact electrically coupled to the p⁺-type semiconductor layer;
the drain includes a drain contact electrically coupled to the n-type semiconductor layer; and
the semiconductor device further comprises an isolation layer laterally between the drain contact and the p⁺-type semiconductor layer.

17. The semiconductor device of claim 1, wherein the diode includes a Schottky diode.

18. A method comprising:
forming a semiconductor layer stack on a substrate, the semiconductor layer stack including a non-silicon channel layer and a barrier layer in the channel layer, wherein at least one of the substrate or the semiconductor layer stack includes a diode;
forming a gate on a side of the barrier layer opposing the channel layer;
forming a source on or in the semiconductor layer stack, the source electrically coupled to a first terminal of the diode; and
forming a drain on or in the semiconductor layer stack, the drain electrically coupled to a second terminal of the diode.

19. The method of claim 18, wherein:
the substrate includes at least one of silicon, silicon carbide, silicon on insulator (SOI), sapphire, Gallium nitride (GaN), engineered GaN, or another semiconductor material having a bandgap wider than a bandgap of silicon; and
the channel layer includes at least one of GaN, AlGaN, or InAlN.

20. The method of claim 18, further comprising, before forming the semiconductor layer stack on the substrate:
forming an n⁺-type semiconductor layer in a layer of the substrate;
forming a p-type semiconductor layer on the n⁺-type semiconductor layer to form the diode in the substrate; and
forming a p⁺-type region in the p-type semiconductor layer,
wherein forming the drain on or in the semiconductor layer stack includes forming a drain contact electrically coupled to the n⁺-type semiconductor layer,
wherein forming the source on or in the semiconductor layer stack includes forming a source contact electrically coupled to the p⁺-type region, and
wherein the method further comprises forming an isolation layer to electrically isolate the drain contact from the p-type semiconductor layer.

21. The method of claim 18, further comprising, before forming the semiconductor layer stack on the substrate:
forming a p⁺-type region and an n⁺-type region in a p-doped semiconductor layer of the substrate, the n⁺-type region and the p-doped semiconductor layer forming the diode in the substrate,
wherein forming the source on or in the semiconductor layer stack includes forming a source contact electrically coupled to the p⁺-type region, and
wherein forming the drain on or in the semiconductor layer stack includes forming a drain contact electrically coupled to the n⁺-type region.

22. The method of claim 18, further comprising, before forming the semiconductor layer stack on the substrate:
forming an n-type semiconductor layer on a p⁺-type semiconductor layer of the substrate, the n-type semiconductor layer and the p⁺-type semiconductor layer forming the diode in the substrate; and
forming an n⁺-type region in the n-type semiconductor layer,
wherein forming the drain on or in the semiconductor layer stack includes forming a drain contact electrically coupled to the n⁺-type region,
wherein forming the source on or in the semiconductor layer stack includes forming a source contact electrically coupled to the p⁺-type semiconductor layer, and
wherein the method further comprises forming an isolation layer to electrically isolate the source contact from the n-type semiconductor layer.

23. The method of claim 18, further comprising, before forming the semiconductor layer stack on the substrate:
forming an n-type semiconductor layer on the substrate; and
forming a p⁺-type region and an n⁺-type region in the n-type semiconductor layer, the p⁺-type region and the n-type semiconductor layer forming the diode in the substrate,
wherein forming the source on or in the semiconductor layer stack includes forming a source contact electrically coupled to the p⁺-type region, and
wherein forming the drain on or in the semiconductor layer stack includes forming a drain contact electrically coupled to the n⁺-type region.

24. The method of claim 18, wherein forming the semiconductor layer stack on the substrate comprises:
forming a p-type semiconductor layer over the substrate; and
forming an n⁺-type semiconductor layer on the p-type semiconductor layer, the n⁺-type semiconductor layer and the p-type semiconductor layer forming the diode,
wherein forming the source on or in the semiconductor layer stack includes forming a source contact electrically coupled to the p-type semiconductor layer,
wherein forming the drain on or in the semiconductor layer stack includes forming a drain contact electrically coupled to the n⁺-type semiconductor layer, and
wherein the method further comprises forming an isolation layer that electrically isolates the source contact from the n⁺-type semiconductor layer.

25. The method of claim 18, wherein forming the semiconductor layer stack on the substrate comprises:
forming an n-type semiconductor layer over the substrate; and
forming a p⁺-type semiconductor layer on the n-type semiconductor layer, the p⁺-type semiconductor layer and the n-type semiconductor layer forming the diode,
wherein forming the source on or in the semiconductor layer stack includes forming a source contact electrically coupled to the p⁺-type semiconductor layer,
wherein forming the drain on or in the semiconductor layer stack includes forming a drain contact electrically coupled to the n-type semiconductor layer, and
wherein the method further comprises forming an isolation layer that electrically isolates the drain contact from the p⁺-type semiconductor layer.
